(19) United States
(12) Patent Application Publication
(10) Pub. No.: US 2025/0216154 A1
(43) Pub. Date: Jul. 3, 2025

(54) THERMAL PROCESSING SYSTEM FOR PROCESSING WORKPIECES

(71) Applicants: Beijing E-Town Semiconductor Technology Co., Ltd., Beijing (CN); Mattson Technology, Inc., Fremont, CA (US)

(72) Inventors: Dieter Hezler, Lonsee (DE); Rolf Bremensdorfer, Bibertal (DE); Alex Wansidler, Blaustein (DE); Jakob Kirmaier, Dornstadt (DE); Philip Fricker, Ulm (DE); Markus Lieberer, Augsburg (DE); Martin Albrecht, Neu-Ulm (DE); Michael Storek, Dornstadt (DE)

(21) Appl. No.: 18/989,746

(22) Filed: Dec. 20, 2024

Related U.S. Application Data
(60) Provisional application No. 63/616,114, filed on Dec. 29, 2023.

(51) Int. Cl. F27B 17/00; F27D 5/00; F27D 7/02; F27D 11/00; G01J 5/00; H01L 21/67; H05B 3/00

(52) U.S. Cl. CPC F27B 17/0025; F27D 5/0037; F27D 7/02; F27D 11/00; H05B 3/0047; G01J 5/0007; H01L 21/67115; H05B 2203/032

(57) ABSTRACT

A thermal processing system for performing thermal processing can include a workpiece support plate configured to support a workpiece and heat source(s) configured to heat the workpiece. The thermal processing system can include one or more domed window(s) disposed between the workpiece support plate and the one or more heat sources. The system includes a temperature measurement configured to generate data indicative of a temperature of the workpiece. The system includes a gas delivery system configured to flow a process gas over the workpiece.

### CROSS-REFERENCE TO RELATED APPLICATIONS

The present application claims the benefit of priority to U.S. Provisional Application 63/616,114, filed Dec. 29, 2023, the entirety of which is incorporated by reference herein.

### FIELD

The present disclosure relates generally to thermal processing systems, such as thermal processing systems operable to perform thermal processing of a workpiece.

### BACKGROUND

A thermal processing chamber as used herein refers to a device that heats workpieces, such as semiconductor workpieces (e.g., semiconductor workpieces). Such devices can include a support plate for supporting one or more workpieces and an energy source for heating the workpieces, such as heating lamps, lasers, or other heat sources. During heat treatment, the workpiece(s) can be heated under controlled conditions according to a processing regime.

Many thermal treatment processes require a workpiece to be heated over a range of temperatures so that various chemical and physical transformations can take place as the workpiece is fabricated into a device(s). During rapid thermal processing, for instance, workpieces can be heated by an array of lamps through the support plate to temperatures from about 300° C. to about 1,200° C. over time durations that are typically less than a few minutes. During these processes, a primary goal can be to reliably and accurately measure a temperature of the workpiece.

### SUMMARY

Aspects and advantages of embodiments of the present disclosure will be set forth in part in the following description, or may be learned from the description, or may be learned through practice of the embodiments.

Example aspects of the present disclosure are directed to a thermal processing system. The thermal processing system includes a processing chamber and a workpiece support plate configured to support a workpiece within the processing chamber. The system includes one or more heat sources configured to heat the workpiece and one or more domed windows disposed between the workpiece support plate and the one or more heat sources. A temperature measurement system configured to generate data indicative of a temperature of the workpiece is also provided. The system includes a gas delivery system configured to flow a process gas over the workpiece supported on the workpiece support plate.

Example aspects of the present disclosure are directed to a thermal processing system. The thermal processing system includes a processing chamber and a workpiece support plate configured to support a workpiece within the processing chamber. The system includes one or more heat sources configured to heat the workpiece. The one or more heat sources can include a circular lamp array including a plurality of lamps configured to heat the workpiece. The system includes one or more windows disposed between the workpiece support plate and the one or more heat sources. A temperature measurement system configured to generate data indicative of a temperature of the workpiece is also provided. The system includes a gas delivery system configured to flow a process gas over the workpiece supported on the workpiece support plate.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example thermal processing system according to example aspects of the present disclosure;

FIG. 2 depicts an example thermal processing system according to example aspects of the present disclosure;

FIG. 3 depicts an example of a portion of a thermal processing system according to example aspects of the present disclosure;

FIG. 4 depicts an example of a portion of a thermal processing system according to example aspects of the present disclosure;

FIG. 5 depicts an example of cooling channels in a lamp plate for a thermal processing system according to example aspects of the present disclosure;

FIG. 6 depicts an example of cooling channels in a lamp plate for a thermal processing system according to example aspects of the present disclosure;

FIG. 7 depicts an example of a portion of a thermal processing system according to example aspects of the present disclosure;

FIG. 8 depicts an example of a lamp for a thermal processing system according to example aspects of the present disclosure;

FIG. 9 depicts an example of a lamp for a thermal processing system according to example aspects of the present disclosure;

FIG. 10 depicts an example of a lamp for a thermal processing system according to example aspects of the present disclosure;

FIG. 11 depicts an example of a lamp for a thermal processing system according to example aspects of the present disclosure;

FIG. 12 depicts an example of a lamp for a thermal processing system according to example aspects of the present disclosure;

FIG. 13 depicts an example of a lamp for a thermal processing system according to example aspects of the present disclosure;

FIG. 14 depicts an example of a lamp for a thermal processing system according to example aspects of the present disclosure;

FIG. 15 depicts an example of a lamp array for a thermal processing system according to example aspects of the present disclosure;

FIG. 16 depicts an example of a lamp array for a thermal processing system according to example aspects of the present disclosure;

FIG. 17 depicts a cross-sectional portion of an example of a top lamp array and bottom lamp array for a thermal processing system according to example aspects of the present disclosure;

FIG. 18 depicts an example of a portion of a thermal processing system according to example aspects of the present disclosure;

FIG. 19 depicts an example of a portion of a thermal processing system according to example aspects of the present disclosure;

FIG. 20 depicts an example of cooling channels in a lamp plate for a thermal processing system according to example aspects of the present disclosure;

FIG. 21 depicts an example of a window for a thermal processing system according to example aspects of the present disclosure;

FIG. 22 depicts a cross-sectional view of a window for a thermal processing system according to example aspects of the present disclosure;

FIG. 23 depicts a cross-sectional view of a window for a thermal processing system according to example aspects of the present disclosure;

FIG. 24 depicts an example of a portion of a thermal processing system according to example aspects of the present disclosure;

FIG. 25 depicts an example temperature measurement system according to example aspects of the present disclosure;

FIG. 26 depicts an example thermal processing system configured to measure an emissivity of a workpiece according to example aspects of the present disclosure;

FIG. 27 depicts an example thermal processing system configured to measure a temperature of a workpiece according to example aspects of the present disclosure;

FIG. 28 depicts an example temperature measurement system according to example aspects of the present disclosure;

FIG. 29A depicts a transmittance plot for an example opaque region material according to example aspects of the present disclosure;

FIG. 29B depicts a transmittance plot for an example transparent region material according to example aspects of the present disclosure;

FIG. 30A depicts a transmittance plot for example workpiece types according to example aspects of the present disclosure;

FIG. 30B depicts a transmittance plot of example normalized workpiece transmittance according to example aspects of the present disclosure;

FIG. 31 depicts a method for temperature measurement of a workpiece in a thermal processing system according to example aspects of the present disclosure; and

FIG. 32 depicts a method for calibrating a reference intensity for sensors in a thermal processing system according to example aspects of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Various workpiece processing treatments such as rapid thermal processing, must be performed in processing chambers that are capable of efficiently and effectively controlling process recipes including process temperatures and workpiece temperatures to very tight tolerances in order to increase workpiece throughput and overall process uniformity. As such, thermal processing systems must be capable of accurately controlling process parameters. Furthermore, it has been difficult to obtain accurate workpiece temperature measurements of workpieces thermal processing.

Accordingly, aspects of the present disclosure provide a number of technical effects and benefits. For instance, the thermal processing system of the present disclosure provides a lamp array configured to allow for adjustable zone temperature processing. Further, the thermal processing system allows for the ability to both rapidly heat and cool the workpiece and to monitor the temperature of the workpiece more accurately during processing, thus saving fabrication time and money.

Variations and modifications can be made to these example embodiments of the present disclosure. As used in the specification, the singular forms “a,” “and,” and “the” include plural referents unless the context clearly dictates otherwise. The use of “first,” “second,” “third,” etc., are used as identifiers and are not necessarily indicative of any ordering, implied or otherwise. Example aspects may be discussed with reference to a “substrate,” “workpiece,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value.

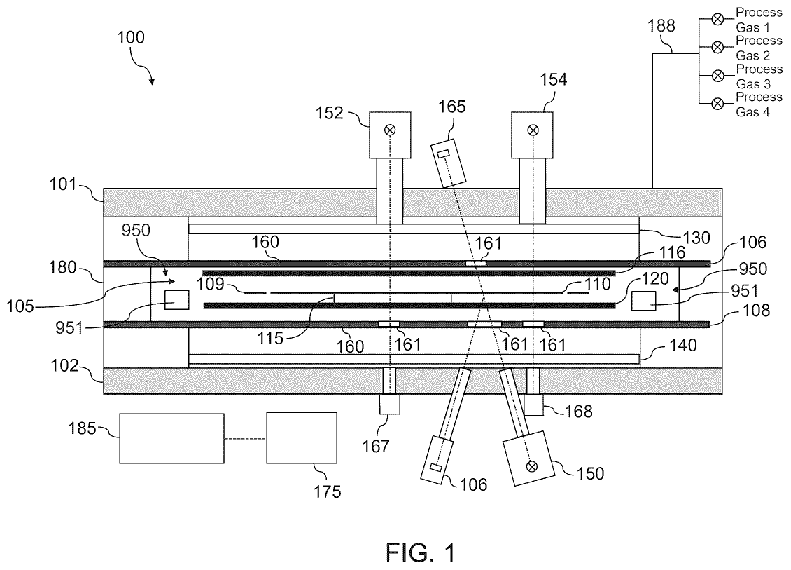

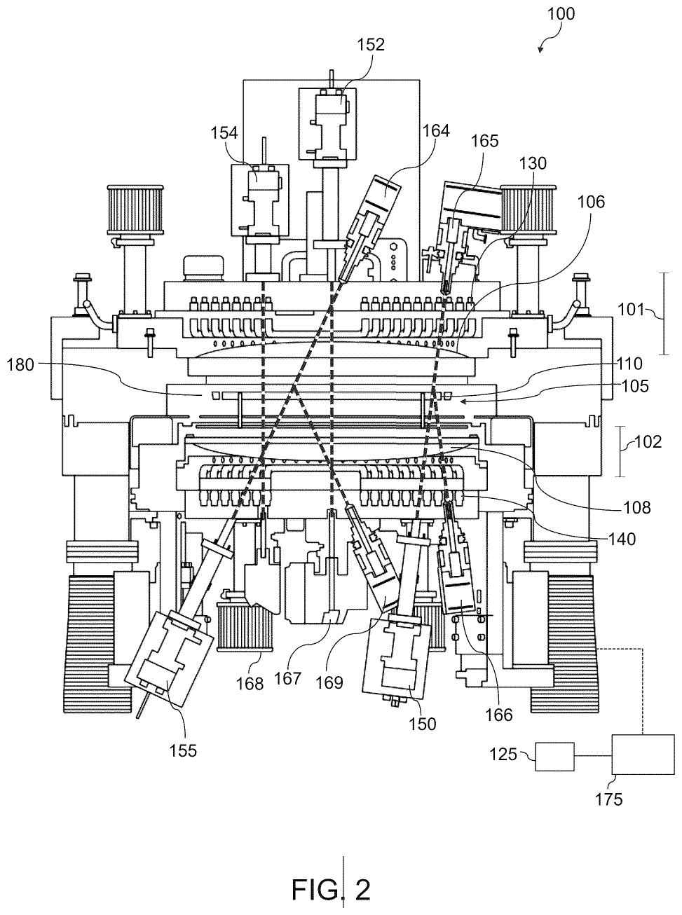

With reference now to the FIGS., example embodiments of the present disclosure will now be discussed in detail. FIGS. 1-2 depict an example rapid thermal processing (RTP) system 100 according to example embodiments of the present disclosure. As illustrated, the RTP system 100 includes an RTP chamber 105 including a top 101 and bottom 102, windows 106, 108, workpiece 110, workpiece support plate 120, heat sources 130, 140 (e.g., heating lamps), infrared emitters 150, 152, 154, 155 sensors 164, 165, 166, 167, 168, 169 (e.g., pyrometers, such as dual-head pyrometers or single-head pyrometers), controller 175, sidewall/door 180, and gas flow controller 185. Workpiece presence sensor (not shown) can also be included and utilized to determine when a workpiece 110 is present in the chamber 105.

The workpiece 110 to be processed is supported in the RTP chamber 105 (e.g., a quartz RTP chamber) by the workpiece support plate 120. The workpiece support plate 120 can be a workpiece support operable to support a workpiece 110 during thermal processing. Workpiece 110 can be or include any suitable workpiece, such as a semiconductor workpiece, such as a silicon workpiece. In some embodiments, workpiece 110 can be or include a lightly doped silicon workpiece. For example, a lightly doped silicon workpiece can be doped such that a resistivity of the silicon workpiece is greater than about 0.1 Ωcm, such as greater than about 1 Ωcm.

Workpiece support plate 120 can be or include any suitable support structure configured to support workpiece 110, such as to support workpiece 110 in RTP chamber 105. In some embodiments, workpiece support plate 120 can be configured to support a plurality of workpieces 110 for simultaneous thermal processing by a thermal processing system. In some embodiments, workpiece support plate 120 can rotate workpiece 110 before, during, and/or after thermal processing. In some embodiments, workpiece support plate 120 can be transparent to and/or otherwise configured to allow at least some electromagnetic radiation to at least partially pass through workpiece support plate 120. For instance, in some embodiments, a material of workpiece support plate 120 can be selected to allow desired electromagnetic radiation to pass through workpiece support plate 120, such as electromagnetic radiation that is emitted by workpiece 110 and/or emitters 150, 152, 154, 155. In some embodiments, workpiece support plate 120 can be or include a quartz material, such as a hydroxyl free quartz material.

Workpiece support plate 120 can include at least one support pin 115 extending from workpiece support plate 120. In some embodiments, workpiece support plate 120 can be spaced from top plate 116. In some embodiments, the support pins 115 and/or the workpiece support plate 120 can transmit heat from heat sources 140 and/or absorb heat from workpiece 110. In some embodiments, the support pins 115, guard ring 109, and top plate 116 can be made of quartz.

A guard ring 109 can be used to lessen edge effects of radiation from one or more edges of the workpiece 110. Sidewall/door 180 allows entry of the workpiece 110 and, when closed, allows the chamber 105 to be sealed, such that thermal processing can be performed on workpiece 110. For example, a process gas can be introduced into the RTP chamber 105. Two banks of heat sources 130, 140 operable to heat the workpiece 110 in the RTP chamber 105 (e.g., lamps, or other suitable heat sources) are shown on either side of the workpiece 110. Windows 106, 108 can be configured to block at least a portion of radiation emitted by the heat sources 130, 140, as described more particularly below.

RTP system 100 can include heat sources 130, 140. In some embodiments, heat sources 130, 140 can include one or more heating lamps. For example, heat sources 130, 140 including one or more heating lamps can emit electromagnetic radiation (e.g., broadband electromagnetic radiation) to heat workpiece 110. In some embodiments, for example, heat sources 130, 140 can be or include arc lamps, tungsten-halogen lamps, and/or any other suitable heating lamp, and/or combination thereof. In some embodiments, directive elements (not depicted) such as, for example, reflectors (e.g., mirrors) can be configured to direct electromagnetic radiation from heat sources 130, 140 into RTP chamber 105. For instance, in embodiments heat source 130 can be utilized to heat a top side of the workpiece 110 while heat source 140 can be utilized to heat a back side of the workpiece 110.

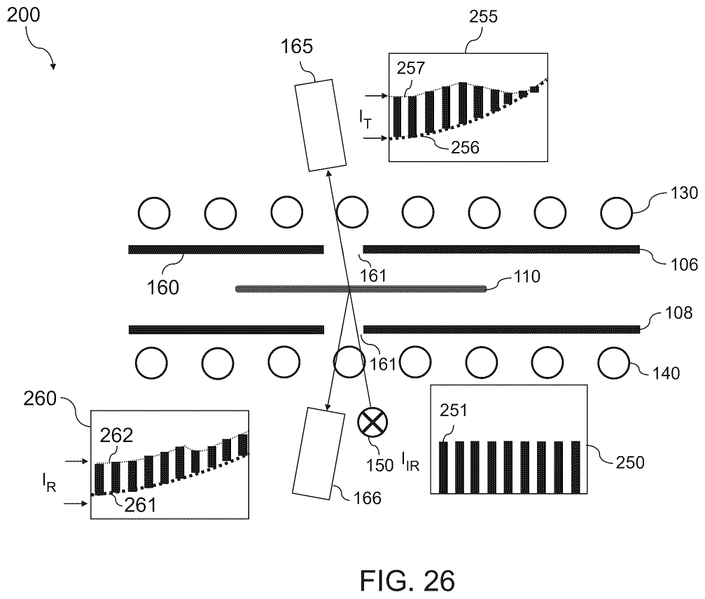

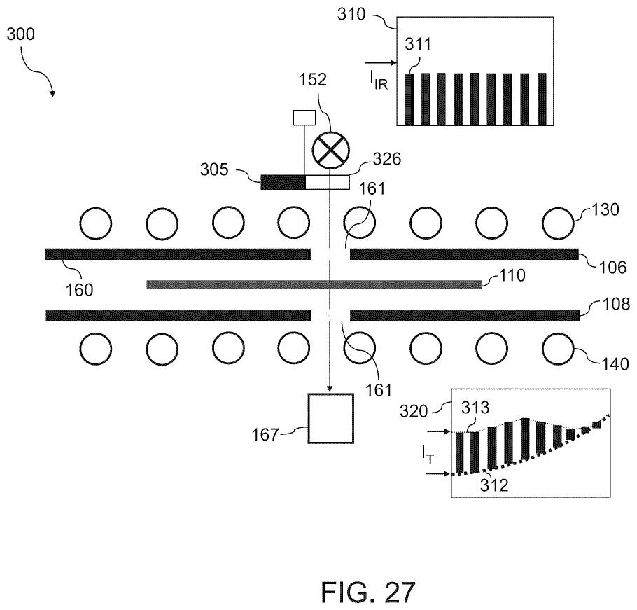

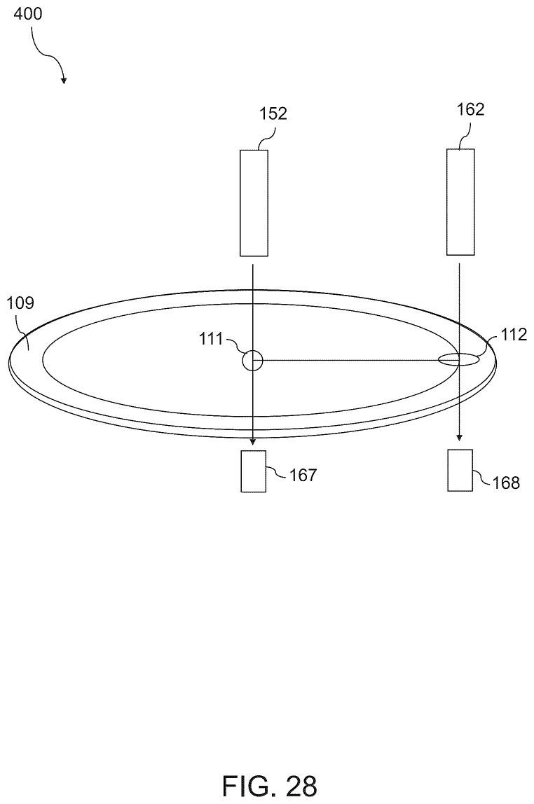

The controller 175 controls various components in RTP chamber to direct thermal processing of workpiece 110. For example, controller 175 can be used to control heat sources 130 and 140. Additionally and/or alternatively, controller 175 can be used to control the gas flow controller 185, the door 180, and/or a temperature measurement system, including, for instance, emitters 150, 152, 154 and/or sensors 165, 166, 167, 168. The controller 175 can be configured to measure a temperature of the workpiece, which will be discussed more particularly with respect to the following figures. For instance, FIG. 26 depicts a thermal processing system 200 including one or more components of thermal processing system 100 configured to perform in-situ emissivity determination of a workpiece. FIG. 27 depicts at least a thermal processing system 300 including one or more components of thermal processing system 100 configured to perform transmittance-based and/or emission-based temperature measurement of a workpiece. Similarly, FIG. 28 depicts a temperature measurement system 400 including one or more components of thermal processing system 100 configured to perform transmittance-based and/or emission-based temperature measurement of a workpiece.

As used herein, a controller, control system, or similar can include one or more processors and one or more memory devices. The one or more processors can be configured to execute computer-readable instructions stored in the one or more memory devices to perform operations, such as any of the operations for controlling a thermal processing system described herein.

Gas controller 185 can control a gas flow through RTP system 100, which can include an inert gas that does not react with the workpiece 110 and/or a reactive gas such as oxygen or nitrogen that reacts with the material of the workpiece 110 (e.g. a semiconductor workpiece, etc.) to form a layer of on the workpiece 110. In some embodiments, an electrical current can be run through the atmosphere in RTP system 100 to produce ions that are reactive with or at a surface of workpiece 110, and to impart extra energy to the surface by bombarding the surface with energetic ions. The gas flow controller 185 can be utilized to provide process gas from a gas delivery system 188 that is configured to flow process gas over the workpiece 110.

Further, as shown in FIG. 1 a magnetic levitation rotation system 950 can be utilized to rotate the workpiece 110 during processing in the processing chamber 105. For instance, the rotation system can include magnetic levitation devices 951 disposed within the processing chamber 105. As shown, the magnetic levitation device(s) 951 can be disposed around the workpiece support plate 120 and the workpiece 110. The magnetic levitation device 951 can be securely fixed in the interior of the chamber 105 and can be controlled by the controller 175 to rotate the workpiece 110. Thus, in embodiments, the magnetic levitation system is disposed in an interior space of the chamber 105.

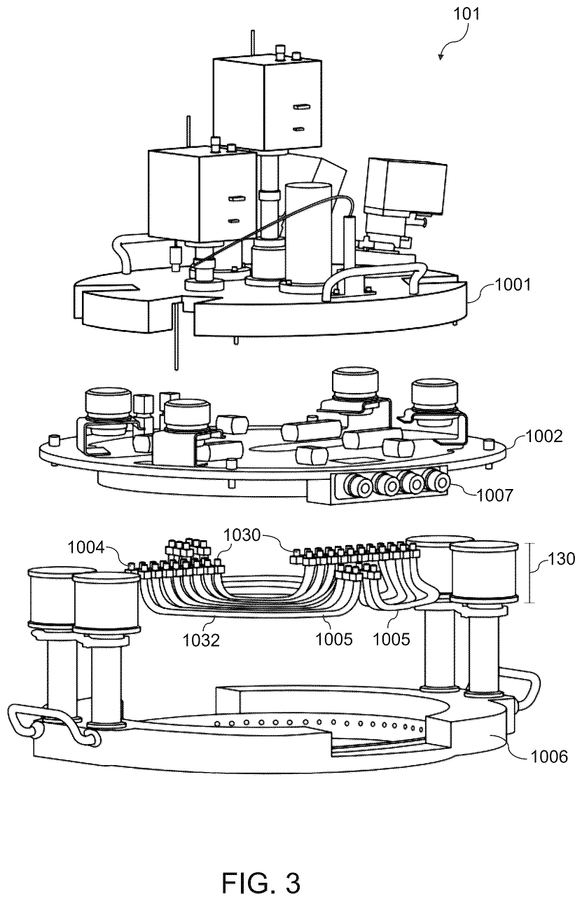

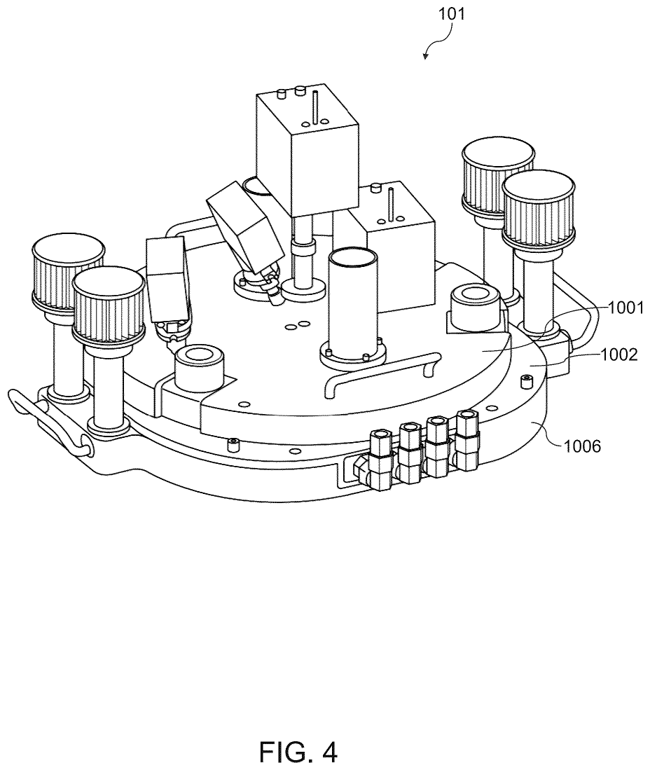

As shown in FIG. 3, heat sources 130 are disposed in a top 101 of the system. As shown, the top 101 can generally include multiple components including a top cover 1001, a lamp plate 1002, a lamp array 1004 including a plurality of lamps 1005, and a bottom 1006. The lamp plate 1002 and the lamp array 1004 can be sandwiched between the top cover 1001 and the bottom 1006 to help shield the lamp plate 1002 and the lamp array 1004 from the external environment. Such a depiction is illustrated in FIG. 4, where the top cover 1001 and the bottom 1006 at least partially enclose the lamp plate and the lamp array 1004. As shown in FIG. 4, only an outer perimeter portion of the lamp plate 1002 extends out from the top cover 1001 and is coupled to the bottom 1006. The lamp plate 1002 can have a variety of reflectors disposed thereon for directing electromagnetic radiation towards a surface of the workpiece 110.

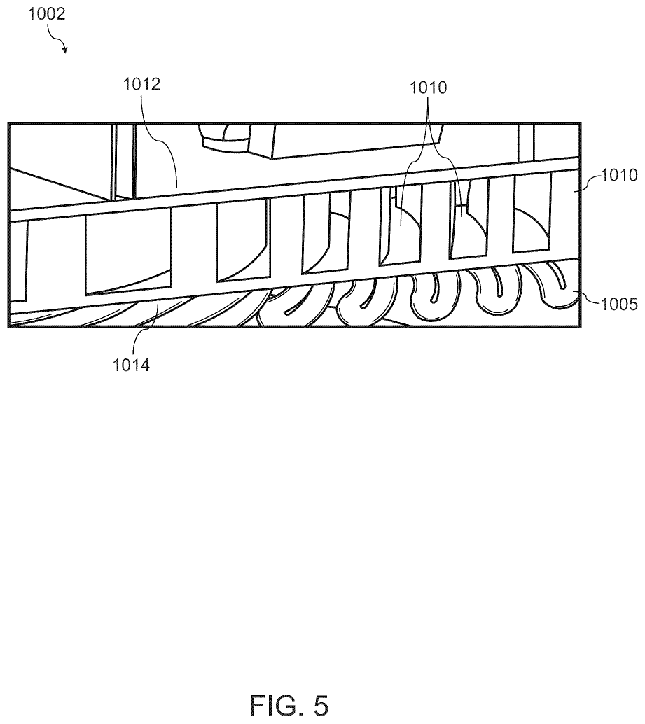

The lamp plate 1002 includes a plurality of channels disposed therein for running cooling fluid therethrough in order to cool the lamps 1005 present in the lamp array 1004. One or more fluid connections 1007 can be coupled to a fluid supply system (not shown) to pump or provide cooling fluid through the channels in the lamp plate 1002. For instance, as illustrated in FIG. 5, one or more fluid channels 1010 can be disposed within the lamp plate 1002. The fluid channels 1010 can be formed in the lamp plate 1002 by any suitable method, however, in embodiments, the fluid channels 1010 are laser etched or formed between a top 1012 and a bottom 1014 of the lamp plate 1002. The channels 1010, in embodiments, can span the entire height of the lamp plate 1002, that is the height between the top 1012 and the bottom 1014 of the lamp plate 1002.

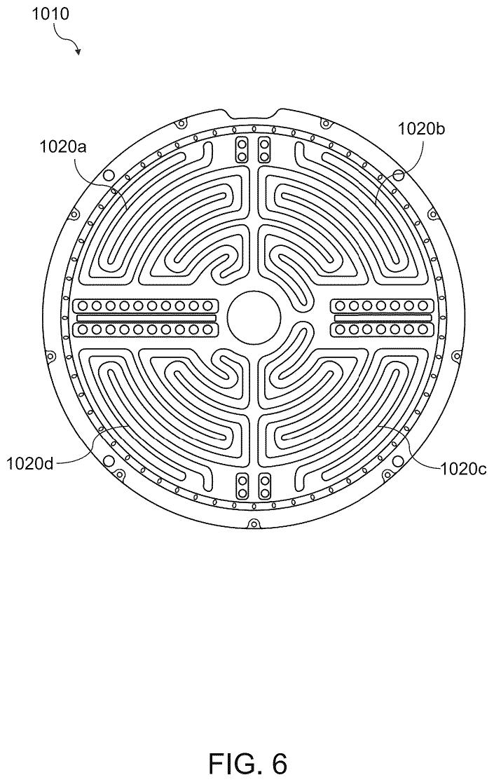

The channels 1010 can be formed in a variety of patterns. One such pattern is depicted in FIG. 6. As shown in FIG. 6 the channels 1010 can form one or more cooling zones 1020. For instance, as shown there are four cooling zones 1020a, 1020b, 1020c, and 1020d that are each independently operably. For instance, cooling zone 1020a can be fluidly coupled to a first fluid connection 1007 that is configured to supply a cooling fluid thereto. Cooling zone 1020a can then flow fluid through a cooling channel 1010 in the lamp plate 1002 to cool a certain area of the lamp array. The cooling fluid can be removed from cooling zone 1020a via a conduit or other suitable tube or device. In such embodiments, each of the cooling zones 1020a, 1020b, 1020c, and 1020d can be fluidly coupled to different fluid connections 1007 and can flow cooling fluid through channels 1010 in a specific zone in order to cool a specific portion or zone of the lamp array 1004. The cooling fluid can be any known suitable cooling fluid, however, in embodiments the cooling fluid includes water, alcohol, or mixtures thereof.

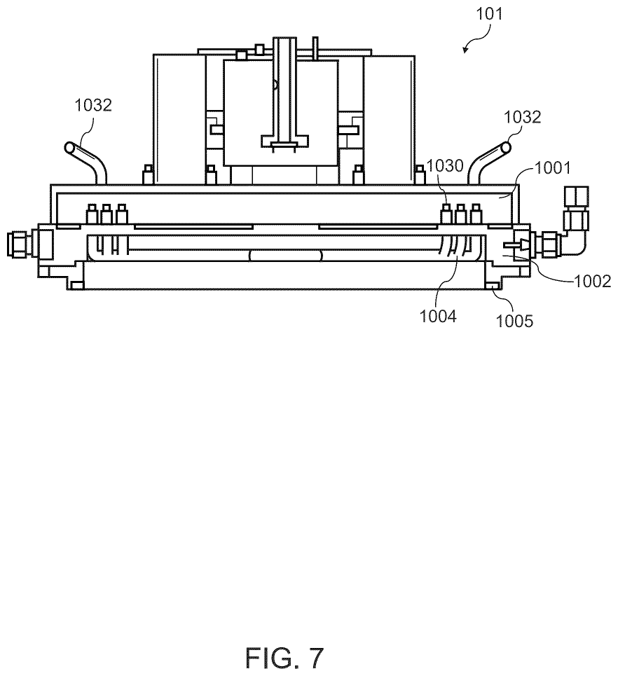

Referring back to FIG. 3, the lamp array 1004 includes a plurality of lamps 1005 each having one or more connections 1030 to couple each lamp 1005 to the lamp plate 1002 or through the lamp plate 1002 and to one or more connections present in the top cover 1001. As shown in FIG. 7, the top 101 includes a top cover 1001, lamp plate 1002, lamp array 1004 and bottom 1006. Each lamp 1005 of the lamp array 1004 can be coupled to power connections 1032 and can pass through the lamp plate 1002 and extend into the top cover 1001 in order to connect each lamp connection 1030 to one or more power sources 1032 located external to the top 101.

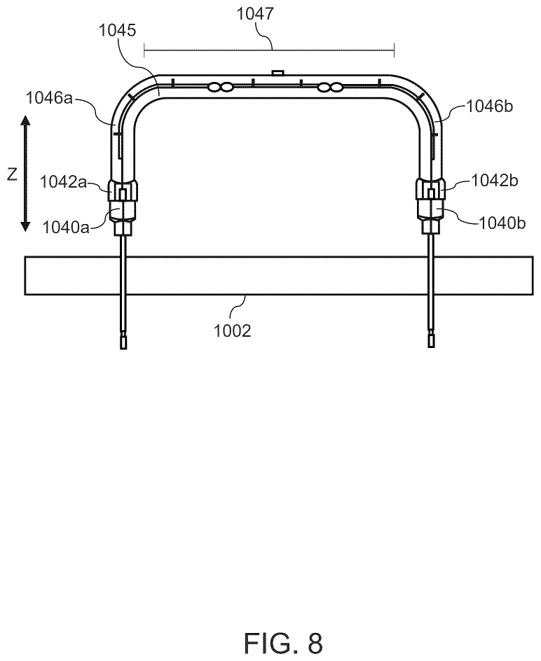

Referring to FIG. 8, an example embodiment of a suitable lamp that can be utilized in the lamp array 1004 is depicted. In such an embodiments, the lamp 1005 includes a first end 1042a and a second end 1042b that terminate into a first lamp connector 1040a and a second lamp connector 1040b, respectively. In between the first lamp end 1042a and the second lamp end 1042b there is a bulb 1045. The bulb 1045 can include a plurality of different shapes, however, in embodiments, the bulb 1045 generally forms a U-shape in the Z-direction as indicated in FIG. 8. For instance, a bulb 1045 is shown including a first extension portion 1046a and a second extension portion 1042b that both extend downward from the lamp plate 1002 in the top 101 as shown in FIG. 8. As shown, the bulb extends generally outward normal to a surface of the lamp plate 1002 from both the first end 1042a and the second end 1042b. However, the bulb 1045 then curves in a U-shape in order to provide a bulb section 1047 that is generally parallel to the surface of the lamp plate 1002.

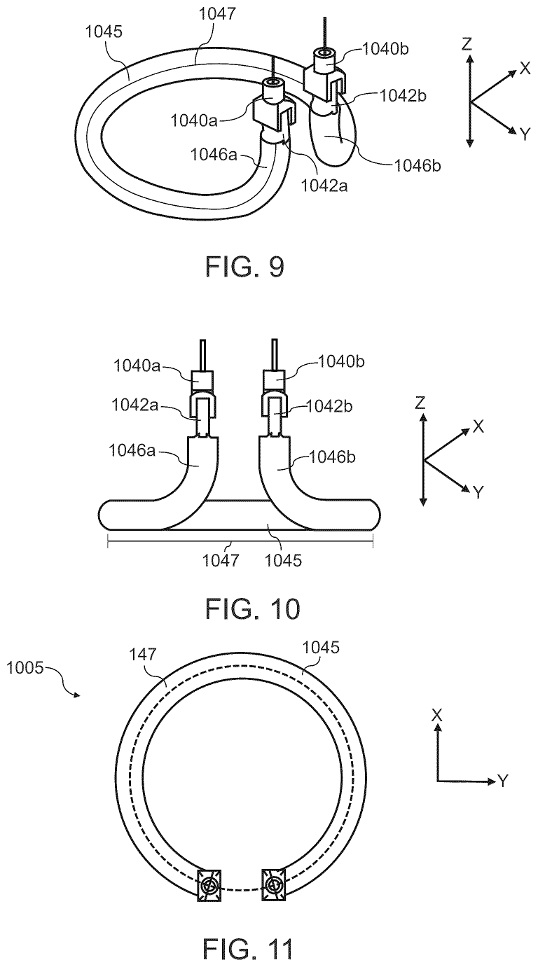

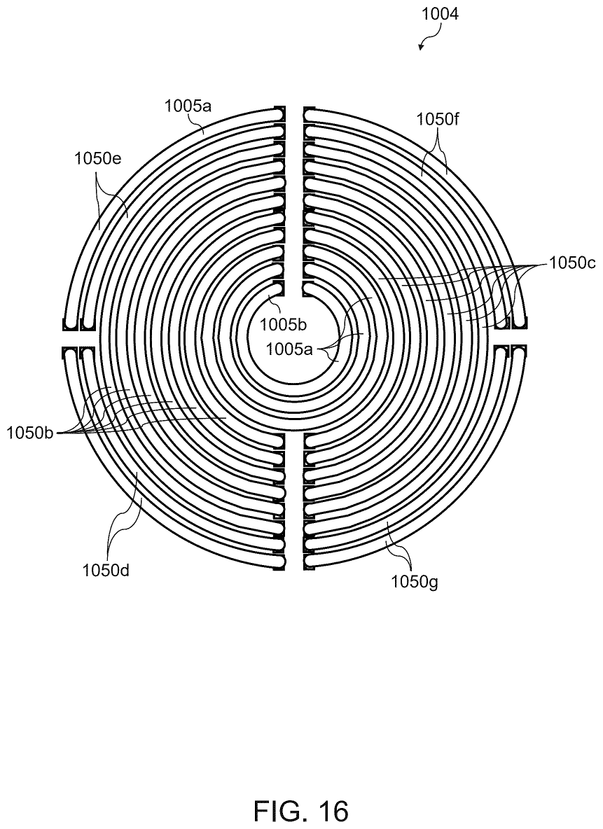

FIGS. 9-11 further illustrate an example embodiment of a lamp 1005 that can be utilized in the lamp array 1004 of the present disclosure. The lamp array 1004 can include a circular-shaped lamp array 1004. As such, certain of the lamps 1005 present in the lamp array 1004 can have a shape as depicted in FIGS. 9-11. For instance, as shown in FIG. 9, the lamp 1005 includes a first end 1042a, first lamp connector 1040a, a second lamp end 1042b, and second lamp connector 1040b, with a bulb 1045 extending between the two respective ends. As shown, however, the bulb 1045 portion, especially the bulb section 1047 that is parallel to the lamp plate can be curved in a C-shaped in the X-Y plane as indicated in FIG. 9. For instance, at least a portion of the bulb section 1047 can define at least from about 300° to about 355° of a circle. The degree of curvature of the bulb 1045 of the lamp 1005 is particularly shown in the top-down view of the bulb in the X-Y plane in FIG. 11. In such embodiments, the degree of curvature of the bulb section 1047 or the total length of the bulb 1045 itself can be increased or decreased in order to form a circular lamp array 1004 as depicted particularly in FIGS. 15-16 and will be discussed further hereinbelow.

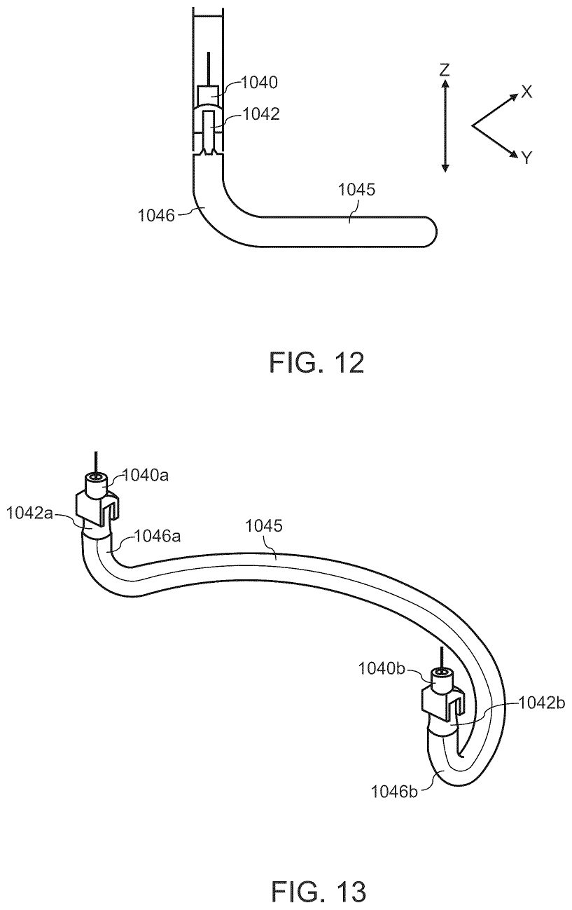

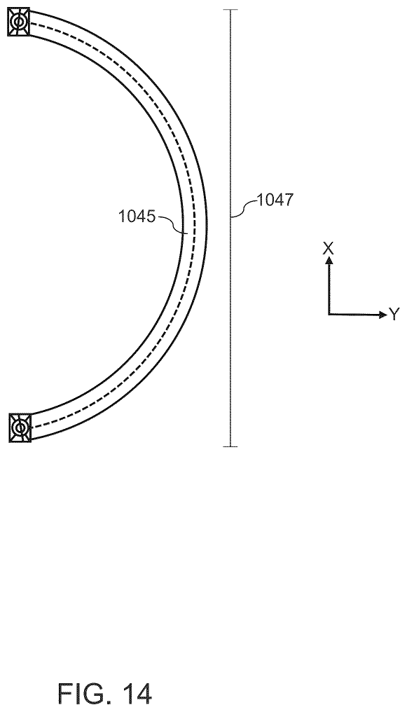

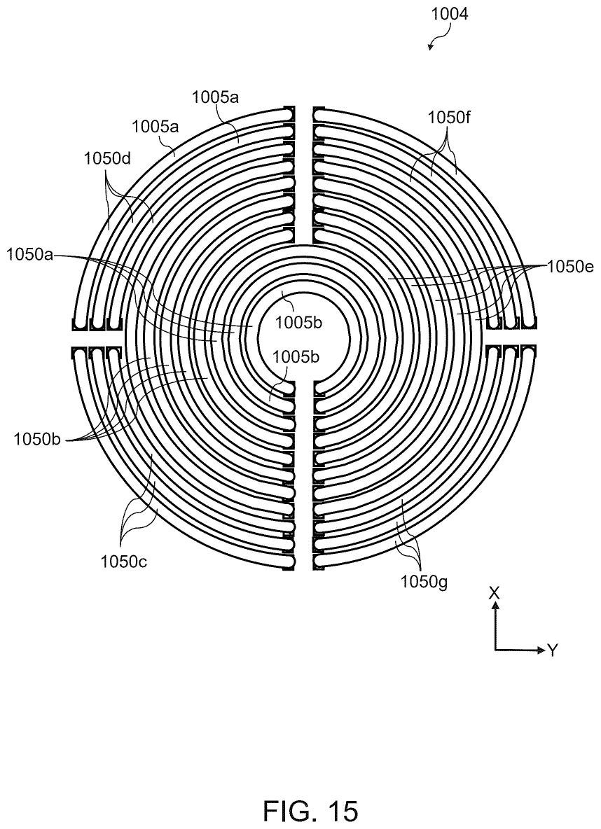

Referring now to FIGS. 12-14, another embodiment of a lamp 1005 is depicted. In such an embodiments, the lamp 1005 includes a first end 1042a and a second end 1042b along with a first lamp connector 1040a and second lamp connector 1040b. A bulb 1045 extends between the two respective ends. As shown, however, the bulb 1045 portion, especially the bulb section 1047 that is parallel to the lamp plate 1002 can be curved in a C-shaped in the X-Y plane as indicated in FIGS. 12 and 14. For instance, at least a portion of the bulb section 1047 can define about 180° or less of a full circle. Notably, the degree of curvature of the bulbs 1045 of the lamps embodied in FIGS. 12-14 have a total degree of curvature that is less than about 180° of the circle. Similar to the bulbs of FIGS. 9-11, the degree of curvature of the bulb section 1047 or the total length of the bulb 1045 itself can be increased or decreased in order to form a circular lamp array 1004 as depicted particularly in FIGS. 15-16 as discussed further hereinbelow.

Referring now to FIG. 15-16, the plurality of lamps 1005 can be disposed in a lamp array 1004 generally forming a circular pattern. For instance, FIG. 15 depicts an example bottom up view of a top lamp array (e.g., one associated with a top 101) of the device, while FIG. 16 depicts a bottom down view of an example bottom lamp array associate with a bottom of the device. While a circular pattern is shown and described other patterns can be utilized without departing from the spirit and scope of the present disclosure. As shown in FIG. 15 a variety of lamps such as 1005a (those depicted in FIGS. 12-14) and lamps 1005b (those depicted in FIGS. 9-11) can be utilized in various configurations to provide a circular pattern for the lamp array 1004. As shown, lamps 1005b having a bulb 1045b forming more of a full circle can be utilized for the interior portion of the lamp array 1004 while lamps 1045a forming less of a circle can be utilized for exterior portions of the lamp array 1004. Further, the lamps 1005 can be connected to various connections in groupings or lamp zones 1050 that can each be independently controller. For instance, a first lamp zone 1050a is shown that includes the innermost lamps 1005. A second lamp zone 1050b and third lamp zone 1050c are disposed radially outward from the first lamp zone 1050a. A fourth lamp zone 1050d, fifth lamp zone 1050e, sixth lamp zone 1050f, and seventh lamp zone 1050g are disposed radially outward from the second lamp zone 1050b and the third lamp zone 1050c. Each of the different lamp zones 1050 can be individually operated and controlled and power to each of the lamp zones 1050 can be independently modified in order to adjust workpiece uniformity during processing.

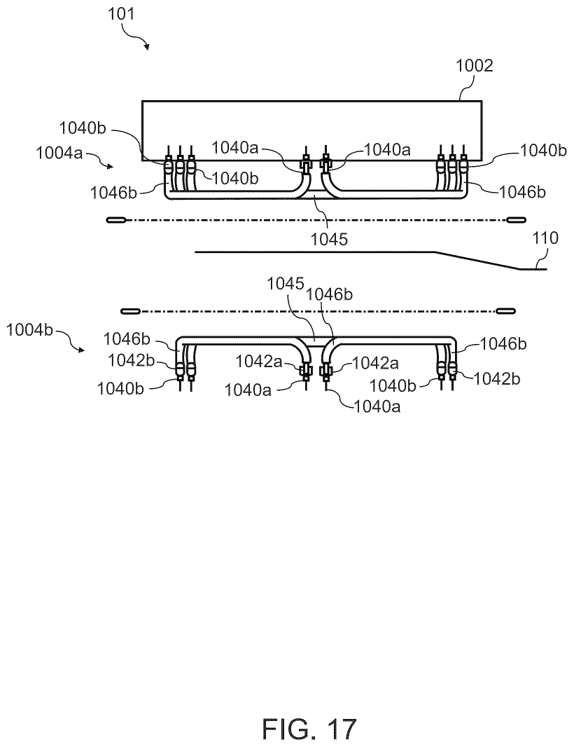

FIG. 17 depicts a portion of an example lamp array 1004 both a top lamp array 1004a and a bottom lamp array 1004b according to example embodiments of the present disclosure. As illustrated, the first lamp array 1004a extends downward in the Z-direction from a lamp plate 1002 associated with a top 101 of the device, while a second lamp array 1004b extends upward from a second lamp plate 1002b associated with a bottom 102 of the device. As depicted, each of the lamps 1005 includes a first end 1042a and second end 1042 having a bulb 1045 extending therebetween and first and second connectors 1040a, 1040b respectively. The workpiece 110 is disposed in the processing chamber between lamp array 1004a and lamp array 1004b.

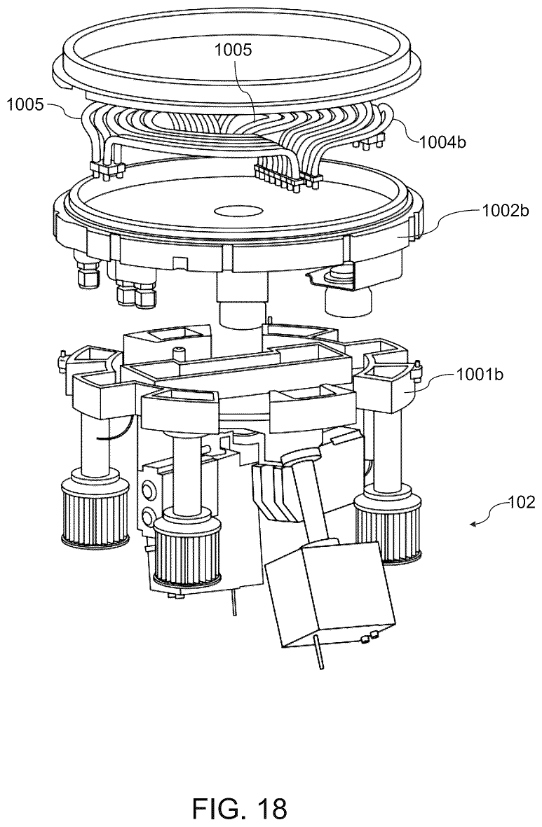

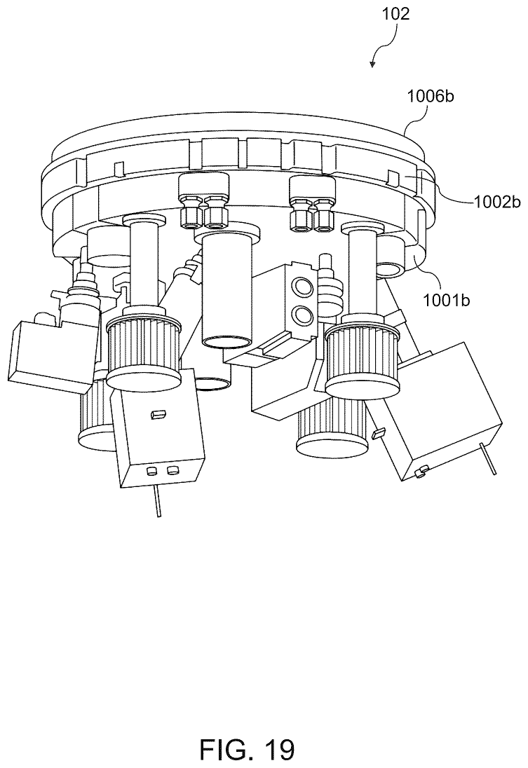

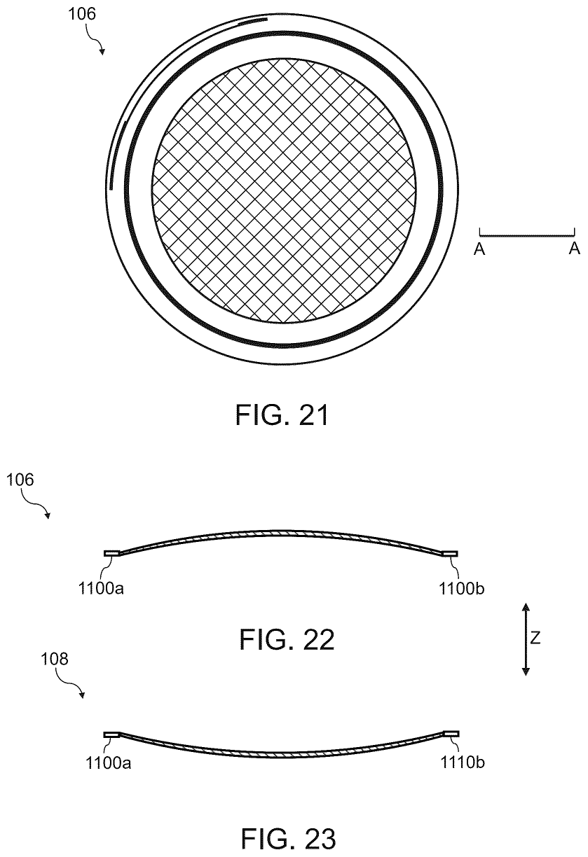

As shown in FIG. 18, the bottom 102 of the system can generally include a multi-component bottom 102 similar to that illustrated in FIG. 3 with respect to the top 101 of the system. As shown, the bottom 102 can generally include multiple components including a bottom cover 1001b, a lamp plate 1002b, a lamp array 1004b including a plurality of lamps 1005b, and a bottom 1006b. The lamp plate 1002b and the lamp array 1004b can be sandwiched between the bottom cover 1001b and the bottom 1006b to help shield the lamp plate 1002b and the lamp array 1004b from the external environment. Such a depiction is illustrated in FIG. 21, where the bottom cover 1001b and the bottom 1006b at least partially enclose the lamp plate and the lamp array 1004b. As shown in FIG. 19, only an outer perimeter portion of the lamp plate 1002b extends out from the bottom cover 1001b and is coupled to the bottom 1006b. Similar to the top 101, the lamp plate 1002b can include a plurality of channels disposed therein for dispersing cooling fluid through the lamp plate 1002b in order to cool the lamps 1005 in the bottom lamp array 1004b. Similar mechanisms as depicted in FIG. 5 can be utilized in the bottom lamp plate 1002b to cool the bottom lamp array 1004b.

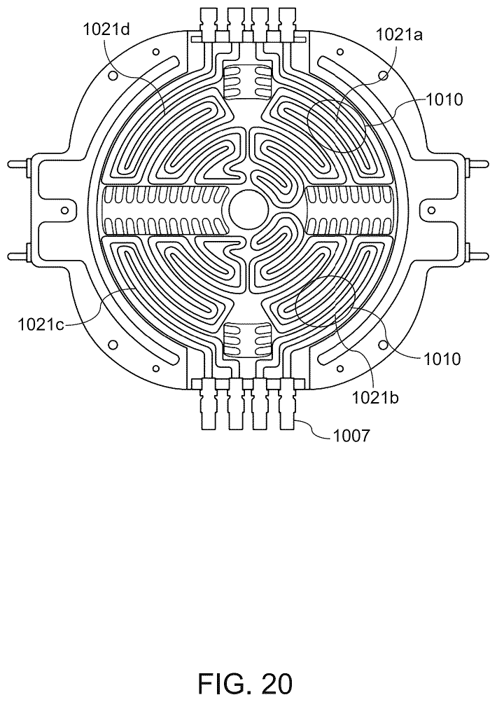

Referring to FIG. 20, the lamp plate 1002b includes a plurality of channels disposed therein for running cooling fluid therethrough in order to cool the lamps 1005 present in the lamp array 1004. One or more fluid connections 1007 can be coupled to a fluid supply system (not shown) to pump or provide cooling fluid through the channels 1010b in the lamp plate 1002b. The fluid channels 1010b can form one or more fluid zones 1021 such as a plurality of fluid zones 1021 that can be independently operated in order to cool various areas of the lamp array 1004b. For instance, the fluid zones can include a first fluid zone 1021a, second fluid zone 1021b, third fluid zone 1021c, and a fourth fluid zone 1021d.

Referring back to FIGS. 1-2, according to example aspects of the present disclosure, windows 106, 108 can be disposed between workpiece 110 and heat sources 130, 140. Windows 106, 108 can be configured to selectively block at least a portion of electromagnetic radiation (e.g., broadband radiation) emitted by heat sources 130, 140 from entering a portion of rapid thermal processing chamber 105. For example, windows 106, 108 can include opaque regions 160 and/or transparent regions 161. As used herein, “opaque” means generally having a transmittance of less than about 0.4 (40%) for a given wavelength, and “transparent” means generally having a transmittance of greater than about 0.4 (40%) for a given wavelength.

Opaque regions 160 and/or transparent regions 161 can be positioned such that the opaque regions 160 block stray radiation at some wavelengths from the heat sources 130, 140, and the transparent regions 161 allow, for example, emitters 150, 152, 154, 155 and/or sensors 164, 165, 166, 167, 168, 169 to freely interact with radiation in RTP chamber 105 at the wavelengths blocked by opaque regions 160. In this way, the windows 106, 108 can effectively shield the RTP chamber 105 from contamination by heat sources 130, 140 at given wavelengths while still allowing the heat sources 130, 140 to heat workpiece 110. Opaque regions 160 and transparent regions 161 can generally be defined as opaque and transparent, respectively, to a particular wavelength; that is, for at least electromagnetic radiation at the particular wavelength, the opaque regions 160 are opaque and the transparent regions 161 are transparent.

Chamber windows 106, 108, including opaque regions 160 and/or transparent regions 161, can be formed of any suitable material and/or construction. In some embodiments, chamber windows 106, 108 can be or include a quartz material. Furthermore, in some embodiments, opaque regions 160 can be or include hydroxyl (OH) containing quartz, such as hydroxyl doped quartz (e.g., quartz that is doped with hydroxyl), and/or transparent regions 161 can be or include hydroxyl free quartz (e.g., quartz that is not doped with hydroxyl). Advantages of hydroxyl doped quartz and hydroxyl free quartz can include an ease of manufacturing. For instance, the hydroxyl free quartz regions can be shielded during hydroxyl doping of a monolithic quartz window to produce both hydroxyl doped regions (e.g., opaque regions) and hydroxyl free regions (e.g., transparent regions) in the monolithic window. Additionally, hydroxyl doped quartz can exhibit desirable wavelength blocking properties in accordance with the present disclosure. For instance, hydroxyl doped quartz can block radiation having a wavelength of about 2.7 micrometers, which can correspond to a measurement wavelength at which some sensors (e.g., sensors 164, 165, 166, 167, 168, 169) in the thermal processing system 100 operate, while hydroxyl free quartz can be transparent to radiation having a wavelength of about 2.7 micrometers. Thus, the hydroxyl doped quartz regions can shield the sensors (e.g., sensors 164, 165, 166, 167, 168, 169) from stray radiation in the rapid thermal processing chamber 105 (e.g., from heat sources 130, 140), and the hydroxyl free quartz regions can be disposed at least partially within a field of view of the sensors to allow the sensors to obtain measurements within the thermal processing system. Additionally, hydroxyl doped quartz can be partially opaque (e.g., have a transmittance around 0.6, or 60%) to radiation having a wavelength of about 2.3 micrometers, which can at least partially reduce contamination from stray radiation in rapid thermal processing system 100 (e.g., from heat sources 130, 140).

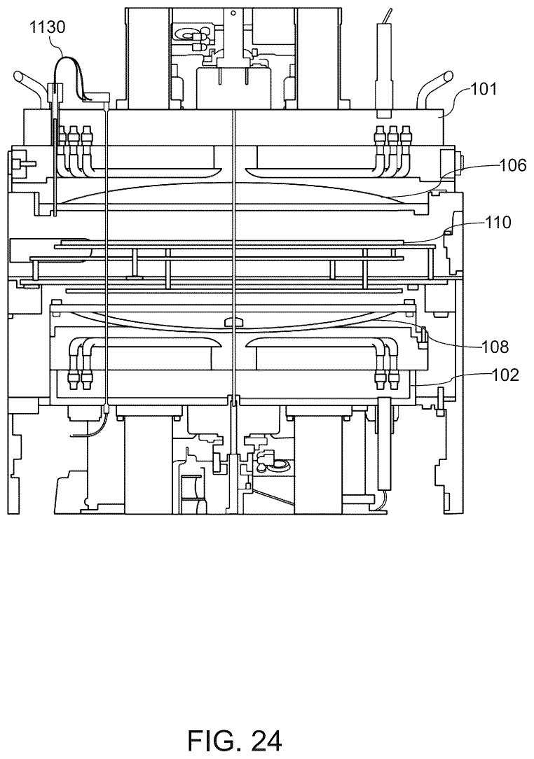

As illustrated in FIGS. 2 and 21-23, the one or more windows 106 and 108 can include dome-shaped windows 106 and 108. For instance, FIG. 21 illustrates a top down view of windows 106,108 and FIG. 22-23 illustrates a cross-section of the window taken along the A-A plane generally in the Z-direction as shown. As illustrated, the window 106 has a first end 1100a and a second end 1100b with a curved portion extending away from the workpiece along a top 101 of the system. For instance, as shown, window 106 has a convex portion extending away from the workpiece and from the center of the processing chamber. FIG. 23 depicts window 108 that is disposed generally underneath of the workpiece 110 or closer to the bottom 102 of the system as compared to the first window 106. As illustrated and similar to window 106, window 108 includes a first end 1100a and a second end 1100b having a curved portion extending away from the workpiece along a bottom 102 of the system. In such embodiments, the window 108 has a convex portion extending away from the workpiece and from the center of the processing chamber. Accordingly, windows 106,108 can both include curved portions creating a circular or ovular configuration with respect to the processing chamber of the system. Such a configuration is illustrated in FIG. 24. Further, as depicted in FIG. 24 one or more temperature sensors 1130 can be utilized to measure the temperature of window 106 or window 108.

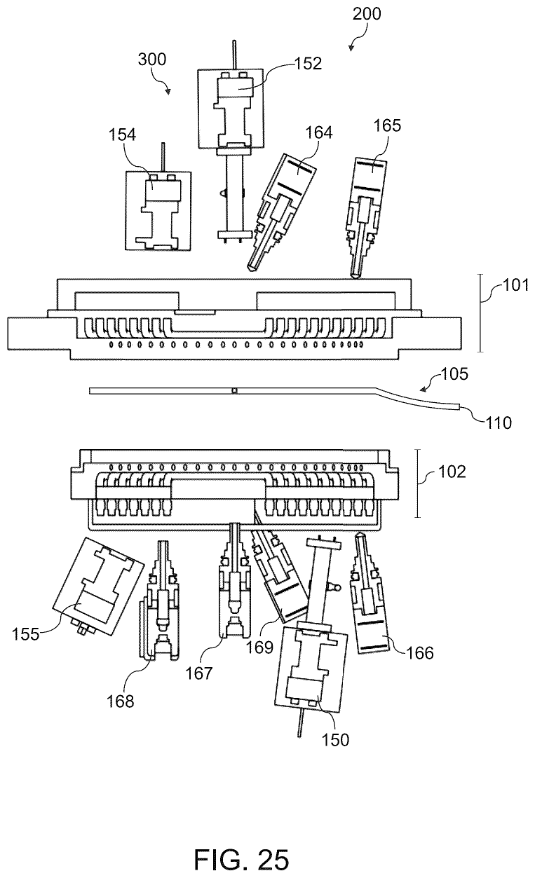

FIGS. 25-27 depict an example thermal processing system 200 for purposes of illustration and discussion. In particular, thermal processing system includes one or more components as discussed with respect to thermal processing system 100 of FIG. 1 and FIG. 2 FIG. 1. In particular, FIG. 25 depicts emitters 150, 152, 154, 155 and sensors 164, 165, 166, 167, 168, and 169. Notably, certain of the emitters 154 and 152 are configured to emit radiation in a plane that is normal to the wafer surface. For instance, emitters 152, 154 are disposed in a top portion of the system 100 and have an emitting surface that is generally parallel to the top of the workpiece 110. Further, sensors 167 and 168 are disposed such that a plane of the sensors 167, 168 is parallel to the surface of the workpiece 110. Sensors 167, 168 are disposed in a bottom portion of the system and can be disposed underneath emitters 152, 154, as shown. Further, certain of the emitters 155, 150 are disposed in a bottom portion of the system and have an emitting surface that is generally angled with respect to the bottom surface of the workpiece 110. Sensors 164, 165, 166, and 169 are disposed such that a plane of the sensor is angled with respect to a surface of the workpiece 110. Emitters 155, 150 and sensors 164, 165, 166, 169 can be utilized to determine an in-situ emissivity measurement of the workpiece 110 in at least two different locations on the workpiece. In embodiments, sensors 167 and 168 can be dual-head pyrometers and sensors 164, 165, 166, and 169 can be single-head pyrometers. Sensors 164, 165, 166, 167, 168, 169 can also each include an optical notch filter disposed at least partially in a field of view of at least one of the plurality of the sensors 164, 165, 166, 167, 168, 169. The optical notch filter is configured to select at least a portion of the measurement wavelength range from a range of wavelengths capable of being measured by the at least one of the sensors 164, 165, 166, 167, 168, 169.

In particular, FIGS. 25-26 depict at least components useful in determining an in-situ emissivity measurement of workpiece 110, including at least emitters 150,155 and sensors 165,166 and 164 and 169. As depicted in FIGS. 25-26, emitters 150,155 can be configured to emit infrared radiation directed at an oblique angle to workpiece 110. A transmitted portion of the emitted radiation emitted by emitters 150,155 is transmitted through workpiece 110 and incident on transmittance sensor 165 and 164, respectively. A reflected portion of the emitted radiation emitted by emitter 150,155 is reflected by workpiece 110 and incident on reflectance sensor 166 and 169, respectively. An emissivity of the workpiece can be determined by the transmitted portion and the emitted portion. For example, the transmittance of workpiece 110 can be represented by the intensity of radiation incident on transmittance sensor 165 and 169. Additionally, the reflectance of workpiece 110 can be represented by the intensity of radiation incident on reflectance sensor 166 and 169. From transmittance and reflectance, transmissivity t and reflectivity p can be determined as a ratio of transmittance and reflectance, respectively, to a reference intensity I₀ which can represent intensities at the sensors 165, 166 and 164, 169 when no workpiece is present in the thermal processing system 200. From that, emissivity & can be calculated as:

$$ε = 1 - ( ρ + τ )$$

According to example aspects of the present disclosure, one or more transparent regions 161 can be disposed at least partially in a field of view of emitters 150,155 and/or sensors 165, 166 and 164,169. For instance, emitter 150 and/or sensors 165, 166 can operate at a measurement wavelength range that the transparent regions 161 are transparent to. Further, emitter 155 and/or sensors 164, 169 can operate at a measurement wavelength range that the transparent regions 161 are transparent to. For example, in some embodiments, emitters 150,155 and/or sensors 165, 166, 164 and 169 can operate at 2.7 micrometers. As illustrated in FIG. 27, the transparent regions 161 can be positioned such that a radiation flow (indicated generally by arrows) is able to flow from emitters 150,155 through the transparent regions 161 and to sensors 165, 166 or 164, 169 without obstruction by windows 106, 108 (e.g., opaque regions 160). Similarly, opaque regions 160 can be disposed in regions on windows 106, 108 that are outside of the radiation flow to shield workpiece 110 and especially sensors 165, 166 and 164, 169 from radiation in the measurement wavelength range from heat sources 130, 140. For example, in some embodiments, transparent regions 161 can be included for sensors and/or emitters operating at 2.7 micrometer wavelengths.

In some embodiments, emitters 150, 155 and/or sensors 164, 165, 166, 169 can be phase-locked. For instance, in some embodiments, emitter 150 and/or sensors 165, 166 can be operated according to a phase-locked regime. For instance, although opaque regions 160 can be configured to block most stray radiation from heat sources 130, 140 at a first wavelength, in some cases stray radiation can nonetheless be perceived by the sensors 164, 165, 166, 169 as discussed above. Operating the emitters 150, 155 and/or sensors 164, 165, 166, 169 according to a phase-locked regime can contribute to improved accuracy in intensity measurements despite the presence of stray radiation.

For instance, in some embodiments, radiation emitted by emitters 150, 155 can be pulsed at a pulsing frequency. The pulsing frequency can be selected to be or include a frequency having little to no radiation components in the thermal processing system 200. For example, in some embodiments, the pulsing frequency can be about 130 Hz. In some embodiments, a pulsing frequency of 130 Hz can be particularly advantageous as the heat sources 130, 140 can emit substantially no radiation having a frequency of 130 Hz. Additionally and/or alternatively, sensors 164, 165, 166, 169 can be phase-locked based on the pulsing frequency. For instance, the thermal processing system 200 (e.g., a controller, such as controller 175 of FIG. 1), can isolate a measurement (e.g., an intensity measurement) from the sensors 164, 165, 166, 169 based on the pulsing frequency. In this way, thermal processing system 200 can reduce interference from stray radiation in measurements from sensors 164, 165, 166, 169.

An example phase locking regime is discussed with respect to plots 250, 255, 260. Plot 250 depicts radiation intensity for radiation I_{IR} emitted within the measurement wavelength range by emitters 150, 155 over time (e.g., over a duration of a thermal process performed on workpiece 110). As illustrated in plot 250, radiation intensity emitted by emitter 150 or emitter 155 can be emitted as pulses 251. For instance, emitters 150, 155 can be pulsed by a chopper wheel (not illustrated). A chopper wheel can include one or more blocking portions and/or one or more passing portions. A chopper wheel can be revolved in a field of view of emitters 150, 155 such that a constant stream of radiation from emitters 150, 155 is intermittently interrupted by blocking portions and passed by passing portions at the pulsing frequency. Thus, a constant stream of radiation emitted by emitters 150,155 can be converted by the revolution of a chopper wheel into a pulsed radiation stream at the pulsing frequency.

Plot 255 depicts transmitted radiation intensity I_{T} measured by transmittance sensor 165 over time. Similarly, plot 260 depicts reflected radiation intensity I_{R} measured by reflectance sensor 166 or reflectance sensor 169 over time. Plots 255 and 260 illustrate that, over time (e.g., as workpiece 110 increases in temperature), stray radiation in the chamber (illustrated by stray radiation curves 256 and 261, respectively) can increase. This can be attributable to, for example, decreasing transparency of workpiece 110 and/or increasing emissions of workpiece 110 with respect to an increased temperature of the workpiece 110, increased intensity of the heat sources 130, 140, and/or various other factors related to thermal processing of workpiece 110.

During a point in time at which the emitter 150 or emitter 155 is not emitting radiation, the sensors 164, 165, 166, 169 can obtain measurements corresponding to the stray radiation curves 256, 261, respectively (e.g., stray radiation measurements). Similarly, during a point in time at which the emitter 150 or emitter 155 is emitting radiation (e.g., pulse 251), the sensors 164, 165, 166, 169 can obtain measurements corresponding to total radiation curves 257, 262, respectively (e.g., total radiation measurements). Thus, transmitted radiation intensity I_{T} (e.g., attributable to transmittance t) can be determined based at least in part the difference between time-coordinated (e.g., subsequent) total radiation measurements (e.g., representing curve 256) and stray radiation measurements (e.g., representing curve 256). Furthermore, transmittance t can be determined by a ratio of the transmitted radiation intensity I_{T} to a reference intensity I₀. Similarly, reflected radiation intensity I_{R} (e.g., attributable to reflectance p) can be determined based at least in part the difference between time-coordinated (e.g., subsequent) total radiation measurements (e.g., representing curve 262) and stray radiation measurements (e.g., representing curve 261). Furthermore, reflectance p can be determined by a ratio of the reflected radiation intensity I_{R} to reference intensity I₀. In some embodiments, reference intensity I₀ can be measured by sensors 164, 165, 166, 169 as a result of a pulse and/or constant radiation from emitters 150, 155 when no workpiece 110 is present in thermal processing system 200. From the transmittance τ and reflectance ρ, the emissivity ε can be calculated by:

$$ε = 1 - ( ρ + τ )$$

FIGS. 25 and 27 depict an example thermal processing system 300 according to example aspects of the present disclosure. Thermal processing system 300 can be configured to perform thermal processing on and/or to measure a temperature of workpiece 110. In particular, thermal processing system can include one or more components as discussed with respect to thermal processing system 100 of FIGS. 1-2. In particular, FIGS. 25 and 27 depict at least components useful in determining a transmittance-based and/or emission-based temperature measurement of workpiece 110, including at least center emitter 152 and center sensor 167. In some embodiments, edge emitter 154 and/or edge sensor 168 can operate similarly to center emitter 152 and/or center sensor 167 on an edge portion of workpiece 110, as discussed with respect to FIG. 27, but are omitted from being depicted in FIG. 27 for the purposes of illustration. This is discussed further below with respect to FIG. 28.

As depicted in FIG. 27, center emitter 152 can be configured to emit infrared radiation directed at an orthogonal angle to a surface of workpiece 110, as illustrated by the arrow in FIG. 27. A transmitted portion of radiation emitted by center emitter 152 is transmitted through workpiece 110 and incident on center sensor 167. In some embodiments, transparent regions 161 of windows 106, 108 can be disposed within a field of view of center emitter 152 and/or sensor 167. For instance, center emitter 152 and/or center sensor 167 can operate at a measurement wavelength range that the transparent regions 161 are transparent to. For example, in some embodiments, center emitter 152 and/or center sensor 167 can operate at 2.7 micrometers. As illustrated in FIG. 27, the transparent regions 161 can be positioned such that a radiation flow (indicated generally by arrows) is able to flow from center emitter 152 through the transparent regions 161 and to center sensor 167, without obstruction by windows 106, 108 (e.g., opaque regions 160). Similarly, opaque regions 160 can be disposed in regions on windows 106, 108 that are outside of the radiation flow to shield workpiece 110 and especially center sensor 167 from radiation in the measurement wavelength range from heat sources 130, 140. For example, in some embodiments, transparent regions 161 can be included for sensors and/or emitters operating at 2.7 micrometer wavelengths.

In some embodiments, however, including transparent regions 161 in windows 106 disposed within a field of view of center emitter 152 can undesirably allow radiation emitted by heat sources 130 to contaminate measurements by center sensor 167 and/or other sensors (not illustrated) in thermal processing system 300. For example, in some embodiments, center sensor 167 can additionally be configured to measure thermal radiation emitted by workpiece 110 at a measurement wavelength range for which the transparent regions 161 are transparent. Radiation emitted by heat sources 130 can have an increased risk of contaminating this workpiece emission measurement if transparent regions 161 are disposed in a field of view of center emitter 152.

One solution to this problem is to omit transparent region 161 in a field of view of center emitter 152 and instead include an opaque region 160. Additionally, center emitter 152 and/or center sensor 167 can be operated at a second wavelength in a measurement wavelength range for which opaque region 160 is at least partially transparent. For example, in some embodiments, the second wavelength can be 2.3 micrometers. In this way, despite the presence of opaque region 160, radiation emitted by center emitter 152 can pass through the windows 106 and 108 and be measured by center sensor 167 without requiring the inclusion of potentially contaminating transparent regions. Furthermore, because of the inclusion of opaque region 160, measurements from center sensor 167 indicative of an intensity of emitted radiation (e.g., emitted radiation measurements) emitted by workpiece 110 (e.g., at temperatures at which workpiece 110 emits radiation, such as above about 600° C.) are not contaminated by the stray radiation. The above discussed solution can introduce an additional problem, however. Because the radiation at the second wavelength from center emitter 152 is able to pass through opaque regions 160, so too can stray radiation at the second wavelength from, for example, heat sources 130, 140.

Thus, in some embodiments, center emitter 152 and/or center sensor 167 can be phase-locked. In some embodiments, center emitter 152 and/or center sensor 167 can be operated according to a phase-locked regime. For instance, although opaque regions 160 can be configured to block most stray radiation from heat sources 130, 140 at a first wavelength, in some cases stray radiation, especially stray radiation at a second wavelength, can nonetheless be perceived by the center sensor 167, as discussed above. Operating the center emitter 152 and/or center sensor 167 according to a phase-locked regime can contribute to improved accuracy in intensity measurements despite the presence of stray radiation.

For instance, in some embodiments, radiation emitted by center emitter 152 can be pulsed at a pulsing frequency. The pulsing frequency can be selected to be or include a frequency having little to no radiation components in the thermal processing system 300. For example, in some embodiments, the pulsing frequency can be about 130 Hz. In some embodiments, a pulsing frequency of 130 Hz can be particularly advantageous as the heat sources 130, 140 can emit substantially no radiation having a frequency of 130 Hz. Additionally and/or alternatively, center sensor 167 can be phase-locked based on the pulsing frequency. For instance, the thermal processing system 300 (e.g., a controller, such as controller 175 of FIG. 1), can isolate a measurement (e.g., an intensity measurement) from the center sensor 167 based on the pulsing frequency. In this way, thermal processing system 300 can reduce interference from stray radiation in measurements from center sensor 167.

An example phase locking regime is discussed with respect to plots 310 and 320. Plot 310 depicts radiation intensity for radiation I_{IR} emitted within the measurement wavelength range by center emitter 152 over time (e.g., over a duration of a thermal process performed on workpiece 110). Plot 320 depicts transmitted radiation intensity I_{T} measured by center sensor 167 over time. As illustrated in plot 310, radiation intensity emitted by center emitter 152 can be emitted as pulses 311. For instance, center emitter 152 can be pulsed by chopper wheel 302. Chopper wheel 302 can include one or more blocking portions 305 and/or one or more passing portions 306. Chopper wheel 302 can be revolved in a field of view of center emitter 152 such that a constant stream of radiation from center emitter 152 is intermittently interrupted by blocking portions 305 and passed by passing portions 306 at the pulsing frequency. Thus, a constant stream of radiation emitted by center emitter 152 can be converted by the revolution of chopper wheel 302 into a pulsed radiation stream at the pulsing frequency.

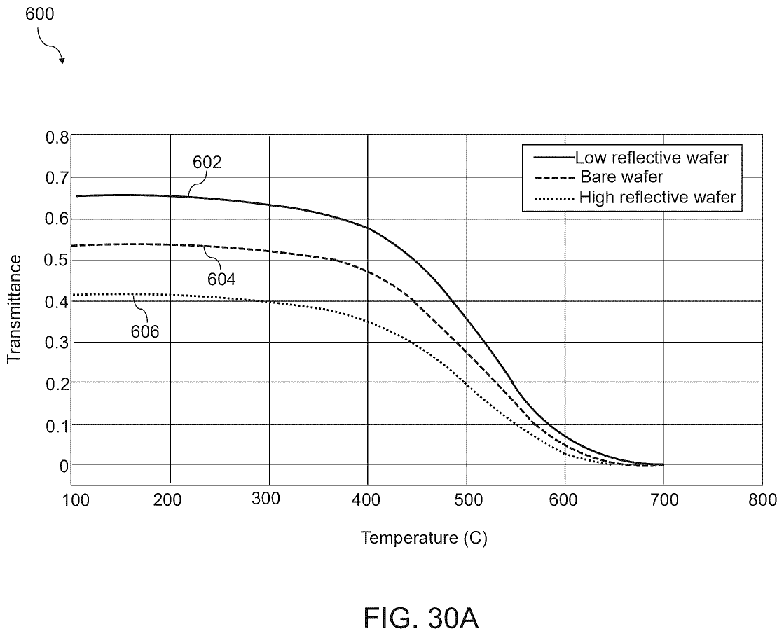

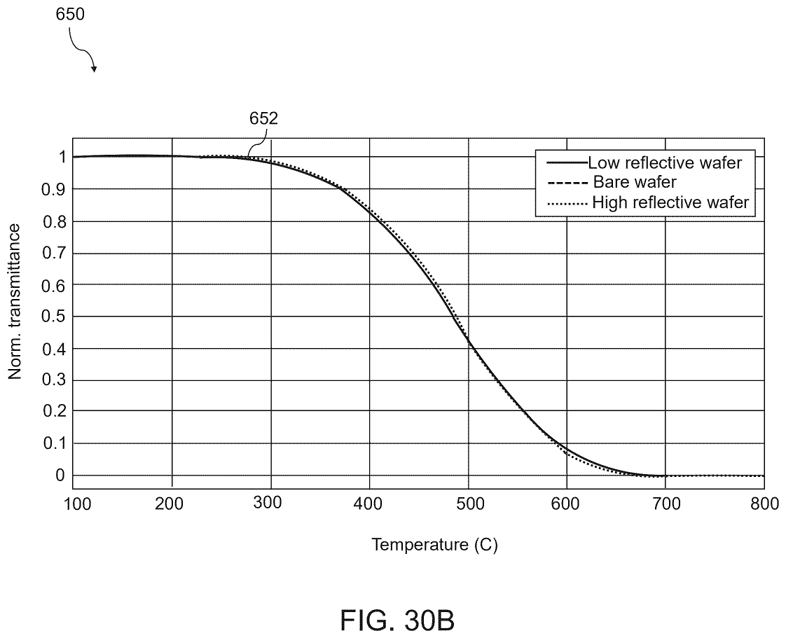

During a point in time at which the center emitter 152 is not emitting radiation, the center sensor 167 can obtain measurements corresponding to the stray radiation curve 312 (e.g., stray radiation measurements). Similarly, during a point in time at which the center emitter 152 is emitting radiation (e.g., pulse 311), the center sensor 167 can obtain measurements corresponding to a total radiation curve 313 (e.g., total radiation measurements). Thus, transmitted radiation intensity I_{T} (e.g., attributable to transmittance t) can be determined based at least in part the difference between time-coordinated (e.g., subsequent) total radiation measurements (e.g., representing curve 313) and stray radiation measurements (e.g., representing curve 312). Furthermore, transmittance τ can be determined by a ratio of the transmitted radiation intensity I_{T} to a reference intensity I₀. For example, reference intensity I₀ can be measured by center sensor 167 as a result of a pulse and/or constant radiation from center emitter 152 when no workpiece 110 is present in thermal processing system 300. The transmittance τ can be compared to a transmittance curve (e.g., workpiece transmittance curves 602, 604, 606 of FIG. 30A that are respective to a particular workpiece composition, and/or normalized workpiece transmittance curve 652 of FIG. 30B) to determine a temperature of the workpiece.

Plot 320 illustrates that, over time (e.g., as workpiece 110 increases in temperature), stray radiation in the chamber (illustrated by stray radiation curve 312) can increase. This can be attributable to, for example, decreasing transparency of workpiece 110 and/or increasing emissions of workpiece 110 with respect to an increased temperature of the workpiece 110, increased intensity of the heat sources 130, 140, and/or various other factors related to thermal processing of workpiece 110. For instance, as can be seen in plot 320, stray radiation curve 312 and total radiation curve 313 tend to converge as time progresses (e.g., as temperature increases). This can be a result of, for example, decreasing transparency of workpiece 110 with respect to increasing temperature. Thus, in some cases (e.g., for silicon workpieces), the transmittance-based temperature measurement as described above can exhibit decreased reliability above a certain temperature (e.g., about 600° C.). Thus, according to example aspects of the present disclosure, a thermal processing system (e.g., any of thermal processing systems 100, 200, 300) can transition from a first temperature measurement process (e.g., a transmittance-based temperature measurement process) to a second temperature measurement process (e.g., an emission-based temperature measurement process) at a temperature threshold. For example, the temperature threshold can be about 600° C. The temperature threshold can correspond to a workpiece temperature at which the workpiece 110 exhibits substantial blackbody radiation at a wavelength that can be detected by center sensor 167. Additionally and/or alternatively, the temperature threshold can correspond to a workpiece temperature at which the workpiece 110 is opaque to radiation emitted by center emitter 152. For instance, in some embodiments, the temperature threshold can correspond to a point at which stray radiation curve 312 and total radiation curve 313 have converged, or, in other words, the magnitude of transmitted radiation intensity I_{T} is below a magnitude threshold.

For instance, in some embodiments, center sensor 167 can be configured to measure radiation emitted by workpiece 110 at the measurement wavelength range. For example, in some embodiments, center sensor 167 can be a dual head pyrometer having a first head configured to measure a first wavelength of a measurement wavelength range. The first wavelength can be or include a wavelength that transparent regions 161 are transparent to and/or opaque regions 160 are opaque to, such as, for example, 2.7 micrometers, in embodiments where the opaque regions 160 include hydroxyl doped quartz. The first wavelength can additionally correspond to a wavelength of blackbody radiation emitted by workpiece 110. Additionally, center sensor 167 can have a second head configured to measure a second wavelength of the measurement wavelength range. The second wavelength can be or include a wavelength that opaque regions 160 are not opaque to, such as, for example, 2.3 micrometers, in embodiments where the opaque regions 160 include hydroxyl doped quartz. The second wavelength can additionally correspond to a wavelength emitted by center emitter 152.

Thus, according to example aspects of the present disclosure, center sensor 167 can obtain transmittance measurements associated with transmittance of workpiece 110 for temperatures of workpiece 110 below a temperature threshold, and can additionally obtain emission measurements associated with an intensity of blackbody radiation emitted by workpiece 110 for temperatures above the temperature threshold. Thus, temperature of workpiece 110 can be determined by transmittance measurements at temperatures below a temperature threshold, as described above. Additionally and/or alternatively, temperature of workpiece 110 can be determined by emission measurements at temperatures above a temperature threshold. For instance, temperature of a workpiece can be determined by emission measurements based on the following equation:

$$T = \frac{h c}{λ k} \cdot \frac{1}{ln ( \frac{2 π {hc}^{2} Δ λ}{{λ}^{5}} \cdot \frac{ε}{{I}_{Wafer}} + 1 )}$$

FIG. 28 depicts an example temperature measurement system 400 according to example aspects of the present disclosure. Temperature measurement system 400 can be configured to measure a temperature of workpiece 110, which can be supported at least in part by support ring 109. Temperature measurement system 400 can include center emitter 152 and edge emitter 154. Additionally, temperature measurement system 400 can include center sensor 167 and edge sensor 168. Emitters 152, 154 and/or sensors 167, 168 can operate as discussed with regard to center emitter 152 and/or center sensor 168 of FIG. 27. For instance, center emitter 152 and center sensor 167 can be disposed such that radiation emitted by center emitter 152 passes through center portion 111 of workpiece 110 and is then incident on center sensor 167. Similarly, edge emitter 154 and edge sensor 168 can be disposed such that radiation emitted by edge emitter 154 passes through edge portion 112 of workpiece 110 and is incident on edge sensor 168. In this way, center sensor 167 can be configured to obtain a temperature measurement of center portion 111 and/or edge sensor 168 can be configured to obtain a temperature measurement of edge portion 112. In some embodiments, center portion 111 can include a portion of the workpiece defined by less than about 50% of a radius r of the workpiece, such as about 10% of the radius r. In some embodiments, edge portion can include a portion of the workpiece defined by greater than about 50% of a radius r of the workpiece, such as about 90% of the radius r.

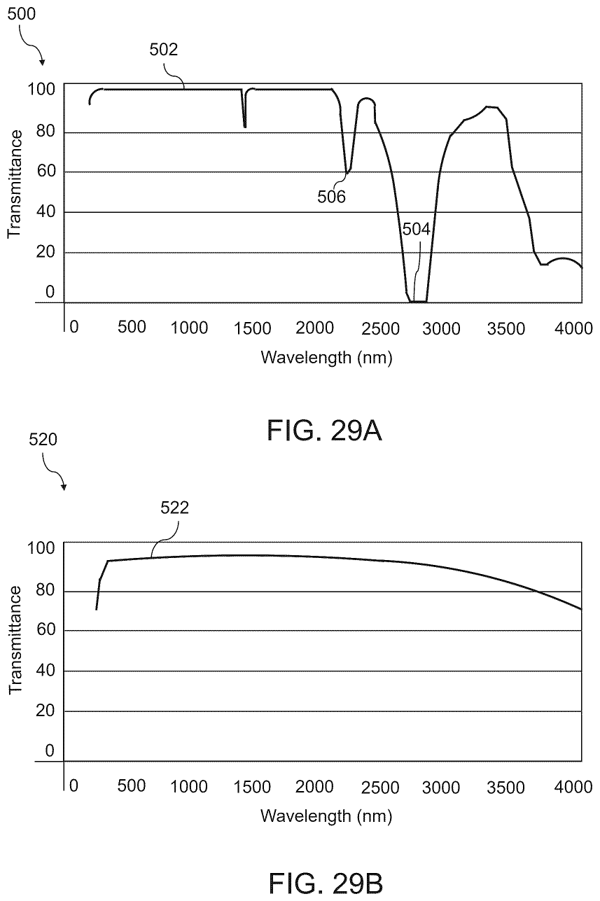

FIG. 29A depicts a plot 500 of an example transmittance curve 502 for an example material composing an example opaque region. For example, transmittance curve 502 is illustrated for an example material such as hydroxyl doped quartz. As illustrated in FIG. 29A, the example opaque region can be substantially opaque to some wavelengths and substantially transparent to others. In particular, the example transmittance curve 502 includes an opaque range 504 and a partially opaque range 506. As discussed herein, a measurement wavelength range can advantageously include wavelengths in the opaque range 504 and/or partially opaque range 506. For instance, radiation in the opaque range 504 and/or partially opaque range 506 can be at least partially blocked by the example opaque region, which can prevent radiation emitted by heating lamps from entering a thermal processing chamber and contaminating measurements from sensors configured to measure the opaque range 504 and/or partially opaque range 506.

FIG. 29B depicts a plot 520 of an example transmittance curve 522 for an example material composing an example transparent region. For example, transmittance curve 522 is illustrated for an example material such as hydroxyl free quartz. As illustrated in FIG. 29B, the example transparent region can be substantially transparent over some wavelengths. Although the example transmittance curve 522 is depicted as substantially transparent over most wavelengths, the example transparent region can additionally include opaque ranges. Generally, it is desirable that the example transparent region is transparent at measurement ranges (e.g., at wavelengths corresponding to opaque range 504 and/or partially opaque range 506 of FIG. 29A).

FIG. 30A depicts a plot 600 of example transmittance curves 602, 604, 606 for three example workpiece types. For instance, curve 602 is associated with a workpiece having a lower reflectivity, curve 604 is associated with a workpiece having a moderate reflectivity (e.g., a bare workpiece), and curve 606 is associated with a workpiece having a higher reflectivity. As illustrated in FIG. 30A, although each of curves 602, 604, 606 follows a general trend, the values of the transmittance for each workpiece can vary based on surface characteristics (e.g., reflectivity) of the workpiece. Thus, FIG. 30B depicts a plot 650 of an example normalized or nominal workpiece transmittance curve 652. As illustrated in FIG. 30B, the normalized workpiece transmittance curve 652 represents transmittance from a maximum of 1 to a minimum of 0 for a particular workpiece, but is irrespective of a particular transmittance value of the workpiece. In other words, the normalized workpiece transmittance curve 652 can be similar and/or identical for each of a low reflective workpiece, a bare workpiece, and/or a high reflective workpiece. Thus, a normalized transmittance measurement obtained for a workpiece can be compared to normalized workpiece transmittance curve 652 such that transmittance can be directly correlated to temperature, irrespective of surface characteristics of a workpiece.

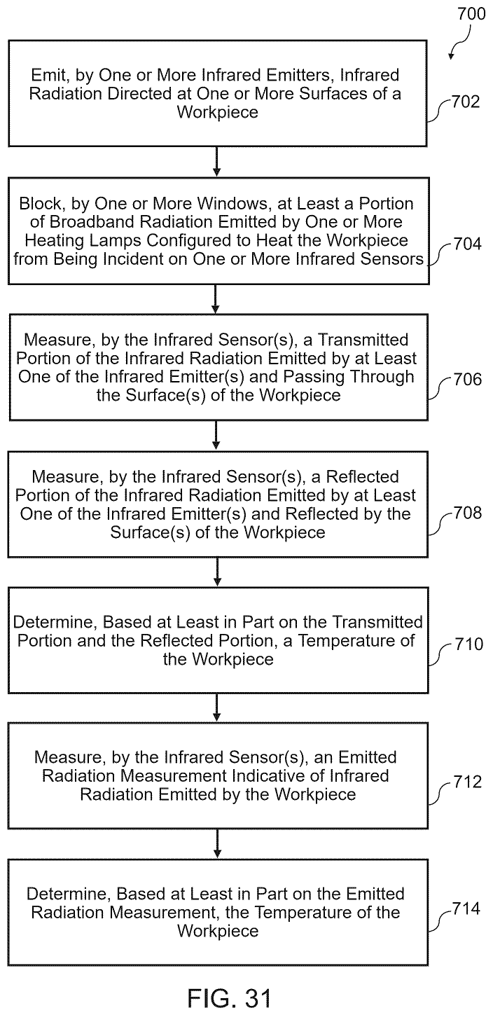

FIG. 31 depicts a flowchart of an example method 700 for measuring a temperature of a workpiece in a thermal processing system, such as, for example, the thermal processing systems 100, 200, or 300 of FIGS. 1-2. FIG. 31 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various additional steps (not illustrated) can be performed without deviating from the scope of the present disclosure.

The method 700 can include, at 702, emitting, by one or more infrared emitters, infrared radiation directed at one or more surfaces of a workpiece. For example, in some embodiments, one or more infrared emitters can emit radiation having a first wavelength and one or more infrared emitters can emit radiation having a second wavelength.

The method 700 can include, at 704, blocking, by one or more windows, at least a portion of broadband radiation emitted by one or more heating lamps configured to heat the workpiece from being incident on one or more infrared sensors. For example, in some embodiments, the one or more windows can block at least a portion of the broadband radiation that is within at least a portion of a measurement range.

The method 700 can include, at 706, measuring, by the one or more infrared sensors, a transmitted portion of the infrared radiation emitted by at least one of the one or more infrared emitters and passing through the one or more surfaces of the workpiece. For example, a first portion of the transmitted portion can be incident on a first transmittance sensor to obtain a first transmittance measurement. The first transmitted portion can correspond to an emitter and/or sensor of an emissivity measurement system. The first transmitted portion can, in some embodiments, have an associated first wavelength. Additionally and/or alternatively, a second portion of the transmitted portion can be incident on at least one second transmittance sensor to obtain at least one second transmittance measurement. In some embodiments, the at least one second transmittance sensor can additionally be configured to measure radiation emitted by a workpiece. In some embodiments, the second transmitted portion can have an associated second wavelength. In some embodiments, the first wavelength can be blocked by the one or more windows and/or the second wavelength can be at least partially passed by the one or more windows. For example, in some embodiments, the first transmitted portion is associated with a first wavelength of the measurement wavelength range and the second transmitted portion is associated with a second wavelength of the measurement wavelength range, wherein the one or more windows block radiation at the first wavelength and allow radiation at the second wavelength.

The method 700 can include, at 708, measuring, by the one or more infrared sensors, a reflected portion of the infrared radiation emitted by at least one of the one or more infrared emitters and reflected by the one or more surfaces of the workpiece. For example, the reflected portion can be incident on a reflectance sensor to obtain a reflectance measurement. In some embodiments, the reflectance sensor can be a portion of an emissivity measurement system.

In some embodiments, measuring, by the one or more infrared sensors, a portion of infrared radiation (e.g., a transmitted portion and/or a reflected portion) emitted by at least one of the one or more infrared emitters can include phase-locking the one or more infrared sensors and/or one or more infrared emitters. For example, phase-locking the one or more infrared sensors and/or the one or more infrared emitters can include pulsing at least one of the one or more infrared emitters at a pulsing frequency. As one example of pulsing one or more emitters, a chopper wheel having one or more slits can be revolved in a field of view of the one or more emitters, such that a constant stream of radiation from the one or more emitters is intermittently allowed, at the pulsing frequency, past the chopper wheel. Thus, the constant stream of radiation can be converted by the revolution of the chopper wheel into a pulsed radiation stream at the pulsing frequency.

Additionally and/or alternatively, phase-locking the one or more infrared sensors and/or the one or more infrared emitters can include isolating at least one measurement from the one or more infrared sensors based at least in part on the pulsing frequency. As one example, measurements from the one or more infrared sensors (e.g., measurements indicative of an intensity of radiation incident on the one or more infrared sensors) that are at and/or in phase with the pulsing frequency can be compared to measurements not at the pulsing frequency and/or out of phase with the measurements in phase with the pulsing frequency, such as by subtracting subsequent measurements at double the pulsing frequency. Thus, signal contributions from components at the pulsing frequency (e.g., emitters) can be isolated from interfering components (e.g., stray radiation, such as heat lamps). In other words, sensor measurements that are not phase-locked to the pulsing frequency (e.g., obtained with the same or greater frequency than the pulsing frequency and/or out of phase with the phase-locked measurements) can be indicative of only stray radiation in the chamber and/or sensor measurements that are phase-locked to the pulsing frequency can be indicative of a sum of stray radiation and emitted radiation from an emitter. Thus, a measurement indicative of emitted radiation emitted by the emitters can be isolated by subtracting out the amount of stray radiation indicated by a measurement that is not phase-locked. As one example, if the pulsing frequency is 130 Hz, the sensor can obtain measurements at 260 Hz or greater, such that one or more stray intensity measurements correspond to each phase-locked measurement. In this way, the thermal processing system can reduce interference from stray radiation (e.g., stray light) in measurements from a sensor.

The method 700 can include, at 710, determining, based at least in part on the transmitted portion and the reflected portion, a temperature of the workpiece. The temperature of the workpiece at 710 can be less than about 600° C. For example, in some embodiments, determining the temperature of the workpiece can include determining, based at least in part on the transmitted portion and the reflected portion, an emissivity of the workpiece, and determining, based at least in part on the transmitted portion and the emissivity of the workpiece, the temperature of the workpiece. For example, in some embodiments, the emissivity of the workpiece can be determined based at least in part on the first transmittance measurement and the reflectance measurement.

The method 700 can include, at 712, measuring, by the one or more infrared sensors, an emitted radiation measurement indicative of infrared radiation emitted by the workpiece. For example, the emitted radiation measurement can be indicative of an intensity of infrared radiation emitted by the workpiece and incident on the one or more sensors. According to example aspects of the present disclosure, the emitted radiation measurement can be obtained once the temperature of the workpiece is high enough such that the workpiece ceases to be transparent to infrared radiation from the emitters and/or begins to emit significant blackbody radiation at a wavelength configured to be measured by the one or more infrared sensors (e.g., within at least a portion of the measurement wavelength range).

In some embodiments, the emitted radiation measurement can correspond to a wavelength of infrared radiation that is blocked by the one or more windows. For example, the emitted radiation measurement can correspond to a wavelength that is and/or is included in the portion of the measurement wavelength range. For example, in some embodiments, the emitted radiation measurement can correspond to an intensity of infrared radiation having a wavelength of 2.7 micrometers.

The method 700 can include, at 714, determining, based at least in part on the emitted radiation measurement, the temperature of the workpiece. The temperature of the workpiece at 714 can be greater than about 600° C. For instance, determining the temperature of the workpiece greater than about 600° C. can include comparing the emitted radiation measurement to a blackbody radiation curve associated with the workpiece. The blackbody radiation curve can correlate an intensity of emitted blackbody radiation to temperature such that temperature can be determined based on a measured intensity (e.g., the emitted radiation measurement).

Systems implementing method 700 can experience an increased temperature range over which the temperature of the workpiece can be measured. For instance, the method 700 can include determining, based at least in part on the transmitted portion and the reflected portion, the temperature of the workpiece according to, for instance, steps 702-710 for temperatures at which the emitted radiation measurement cannot be practically obtained (e.g., below about 600° C.). Additionally, the method 700 can include determining, based at least in part on the emitted radiation measurement, the temperature of the workpiece according to, for instance, steps 712-714 for temperatures at which the emitted radiation measurement can be practically obtained (e.g., above about 600° C.).

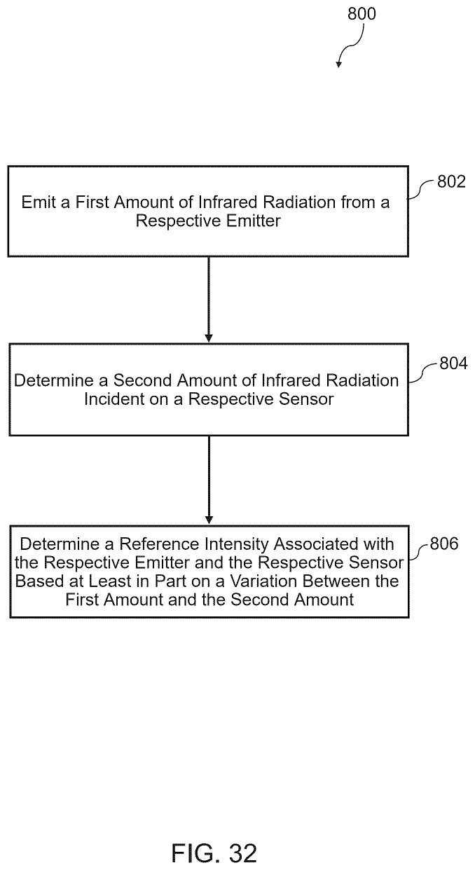

FIG. 32 depicts a flowchart of an example method 800 for calibrating a reference intensity for sensors in a thermal processing system, such as, for example, the thermal processing systems 100, 200, or 300 of FIG. 1-2 or 27-29. FIG. 32 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various additional steps (not illustrated) can be performed without deviating from the scope of the present disclosure.

The method 800 can include, at 802, emitting a first amount of infrared radiation from a respective emitter of the plurality of infrared emitters. The method 800 can include, at 804, determining a second amount of infrared radiation incident on a respective sensor of the plurality of infrared sensors. The method 800 can include, at 806, determining the reference intensity associated with the respective emitter and the respective sensor based at least in part on a variation between the first amount and the second amount.

According to example aspects of the present disclosure, a reference intensity, denoted herein as I₀, can be determined for each of one or more sensors in a thermal processing system. A reference intensity can correspond to radiation emitted by an emitter and/or incident on a sensor when a workpiece is not present in the processing chamber. In other words, the reference intensity can be diminished from the intensity of radiation emitted by an emitter only by contributions from components other than the workpiece in the thermal processing system. This can additionally correspond to a case of 100% transmittance by a workpiece. In some embodiments, the reference intensity can be measured prior to insertion of a workpiece in the processing chamber, such as between thermal processing of two workpieces.

Aspects of the present disclosure including embodiments are also provide below with respect to the following clauses:

A thermal processing system, comprising: a processing chamber; a workpiece support plate configured to support a workpiece within the processing chamber; one or more heat sources configured to heat the workpiece; one or more domed windows disposed between the workpiece support plate and the one or more heat sources; a temperature measurement system configured to generate data indicative of a temperature of the workpiece; and a gas delivery system configured to flow a process gas over the workpiece supported on the workpiece support plate.

The thermal processing according to any preceding clause, wherein temperature measurement system includes one or more infrared sensors, wherein the one or more infrared sensors are disposed such that a plane of the one or more infrared sensors are parallel to a surface of the workpiece.

The thermal processing system of any preceding clause, wherein the one or more infrared sensors are disposed such that a plane of the one or more infrared sensors are angled with respect to a surface of the workpiece.

The thermal processing system of any preceding clause, comprising a workpiece presence sensor configured to detect whether a workpiece is present in the processing chamber.

The thermal processing system of any preceding clause, wherein the one or more heat sources are cooled.

The thermal processing system of any preceding clause, comprising a lamp plate thermally coupled to the one or more heat sources, the lamp plate comprising a plurality of cooling channels configured to provide a cooling fluid.

The thermal processing system of any preceding clause, wherein the lamp plate comprises a plurality of cooling zones, each of the cooling zones are individually controlled.

A thermal processing system, comprising: a processing chamber; a workpiece support plate configured to support a workpiece within the processing chamber; one or more heat sources including a circular lamp array having a plurality of lamps configured to heat the workpiece; one or more windows disposed between the workpiece support plate and the one or more heat sources; a temperature measurement system configured to generate data indicative of a temperature of the workpiece; and a gas delivery system configured to flow a process gas over the workpiece supported on the workpiece support plate.

The thermal processing system of any preceding clause, wherein the one or more windows comprise one or more domed windows.

The thermal processing system of any preceding clause, wherein the one or more windows comprise quartz.

The thermal processing system of any preceding clause, comprising one or more temperature sensors configured to measure the temperature of the one or more windows.

The thermal processing system of any preceding clause, wherein the one or more windows comprise one or more transparent regions that are transparent to at least a portion of electromagnetic radiation within a measurement wavelength range and one or more opaque regions that are opaque to electromagnetic radiation with the portion of the wavelength range.

The thermal processing system of any preceding clause, wherein each of the plurality of lamps extend from a lamp plate in a Z direction towards the workpiece and are U-shaped in a Z-direction.

The thermal processing system of any preceding clause, wherein each of the plurality of lamps are curved in a direction along an X-Y plane.

The thermal processing system of any preceding clause, wherein the circular lamp array comprises a plurality of lamp zones, each of the lamp zones being individually controllable.

The thermal processing system of any preceding clause, comprising a first heat source disposed on a first side of the processing chamber and a second heat source disposed on a second side of the processing chamber that is opposite from the first side.

The thermal processing system of any preceding clause, wherein the first heat source is configured to heat a top side of the workpiece and the second heat source is configured to heat a back side of the workpiece.

The thermal processing system of any preceding clause, comprising a rotation system configured to rotate the workpiece during processing.

The thermal processing system of any preceding clause, wherein the rotation system comprises a magnetic levitation rotation system.

The thermal processing system of any preceding clause, wherein the magnetic levitation rotation system is disposed in an interior space of the processing chamber.

The thermal processing system of any preceding clause, wherein the temperature measurement system comprises a plurality of infrared emitters configured to emit infrared radiation; a plurality of infrared sensors, each infrared sensor corresponding to one of the plurality of infrared emitters, each of the plurality of infrared sensors configured to measure infrared radiation within a measurement wavelength range; and a controller configured to perform operations, the operations comprising: obtaining, from the plurality of infrared sensors, at least one first transmittance measurement, at least one second transmittance measurement, and at least one reflectance measurement associated with the workpiece; determining, based at least in part on the at least one first transmittance measurement, the at least one second transmittance measurement, and the at least one reflectance measurement, a temperature of the workpiece.

The thermal processing system of any preceding clause, wherein the plurality of infrared sensors comprises one or more pyrometers.

The thermal processing system of any preceding clause, comprising at least one optical notch filter disposed at least partially in a field of view of at least one of the plurality of infrared sensors, wherein the optical notch filter is configured to select at least a portion of the measurement wavelength range from a range of wavelengths capable of being measured by the at least one of the plurality of infrared sensors.

The thermal processing system of any preceding clause, wherein one or more infrared sensors are disposed to obtain a first transmittance measurement at a first location of the workpiece, and one or more second infrared sensors are disposed to obtain a second transmittance measurement at a second location of the workpiece, the second location being radially outward from the first location.

The thermal processing system of any preceding clause, wherein the one or more infrared sensors are disposed to obtain a first reflectance measurement at a first location of the workpiece, and one or more second infrared sensors are disposed to obtain a second reflectance measurement at a second location of the workpiece, the second location being radially outward from the first location.

The thermal processing system of any preceding clause, wherein based at least in part on the first transmittance measurement or second transmittance measurement and the first reflectance measurement of the second reflectance measurement, the controller can determine an emissivity of the workpiece.

The thermal processing system of any preceding clause, wherein the one or more infrared sensors are disposed such that a plane of the one or more infrared sensors is parallel to a surface of the workpiece.

The thermal processing system of any preceding clause, wherein the one or more infrared sensors are disposed such that a plane of the sensor is angled with respect to a surface of the workpiece.

The thermal processing system of any preceding clause, comprising a workpiece presence sensor configured to detect whether a workpiece is present in the processing chamber.

The thermal processing system of any preceding clause, wherein the one or more heat sources are cooled.

The thermal processing system of any preceding clause, comprising a cover thermally coupled to the one or more heat sources, the cover comprising a plurality of cooling channels configured to provide a cooling fluid.

The thermal processing system of any preceding clause, wherein the cover comprises a plurality of cooling zones, wherein each of the cooling zones are individually controlled.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A thermal processing system, comprising:
a processing chamber;
a workpiece support plate configured to support a workpiece within the processing chamber;
one or more heat sources configured to heat the workpiece;
one or more domed windows disposed between the workpiece support plate and the one or more heat sources;
a temperature measurement system configured to generate data indicative of a temperature of the workpiece; and
a gas delivery system configured to flow a process gas over the workpiece supported on the workpiece support plate.

2. The thermal processing system of claim 1, wherein the one or more domed windows comprise quartz.

3. The thermal processing system of claim 1, comprising one or more temperature sensors configured to measure a temperature of the one or more domed windows.

4. The thermal processing system of claim 1, wherein the one or more domed windows comprise one or more transparent regions that are transparent to at least a portion of electromagnetic radiation within a measurement wavelength range and one or more opaque regions that are opaque to electromagnetic radiation with the portion of the measurement wavelength range.

5. The thermal processing system of claim 1, wherein the one or more heat sources comprise a lamp array having a plurality of lamps.

6. The thermal processing system of claim 5, wherein each of the plurality of lamps extend from a lamp plate in a Z direction toward the workpiece and are U-shaped in a Z-direction.

7. The thermal processing system of claim 5, wherein each of the plurality of lamps are curved in a direction along an X-Y plane.

8. The thermal processing system of claim 5, wherein the lamp array comprises a plurality of lamp zones, each of the lamp zones being individually controllable.

9. The thermal processing system of claim 5, wherein the lamp array forms a circular lamp array.

10. The thermal processing system of claim 1, comprising a first heat source disposed on a first side of the processing chamber and a second heat source disposed on a second side of the processing chamber that is opposite from the first side.

11. The thermal processing system of claim 10, wherein the first heat source is configured to heat a top side of the workpiece and the second heat source is configured to heat a back side of the workpiece.

12. The thermal processing system of claim 1, comprising a rotation system configured to rotate the workpiece during processing.

13. The thermal processing system of claim 12, wherein the rotation system comprises a magnetic levitation rotation system.

14. The thermal processing system of claim 13, wherein the magnetic levitation rotation system is disposed in an interior space of the processing chamber.

15. The thermal processing system of claim 1, wherein the temperature measurement system comprises a plurality of infrared emitters configured to emit infrared radiation;
a plurality of infrared sensors, each infrared sensor corresponding to one of the plurality of infrared emitters, each of the plurality of infrared sensors configured to measure infrared radiation within a measurement wavelength range; and
a controller configured to perform operations, the operations comprising:
obtaining, from the plurality of infrared sensors, at least one first transmittance measurement, at least one second transmittance measurement, and at least one reflectance measurement associated with the workpiece;
determining, based at least in part on the at least one first transmittance measurement, the at least one second transmittance measurement, and the at least one reflectance measurement, a temperature of the workpiece.

16. The thermal processing system of claim 15, wherein the plurality of infrared sensors comprises one or more pyrometers.

17. The thermal processing system of claim 15, comprising at least one optical notch filter disposed at least partially in a field of view of at least one of the plurality of infrared sensors, wherein the optical notch filter is configured to select at least a portion of the measurement wavelength range from a range of wavelengths capable of being measured by the at least one of the plurality of infrared sensors.

18. The thermal processing system of claim 15, wherein one or more infrared sensors are disposed to obtain a first transmittance measurement at a first location of the workpiece, and one or more second infrared sensors are disposed to obtain a second transmittance measurement at a second location of the workpiece, the second location being radially outward from the first location.

19. The thermal processing system of claim 18, wherein the one or more infrared sensors are disposed to obtain a first reflectance measurement at a first location of the workpiece, and one or more second infrared sensors are disposed to obtain a second reflectance measurement at a second location of the workpiece, the second location being radially outward from the first location.

20. The thermal processing system of claim 19, wherein based at least in part on the first transmittance measurement or second transmittance measurement and the first reflectance measurement of the second reflectance measurement, the controller can determine an emissivity of the workpiece.
